(19) United States
(12) Patent Application Publication
(10) Pub. No.: US 2016/0133502 A1
(43) Pub. Date: May 12, 2016

(54) WAFER TRANSFER ROBOT, METHOD OF CONTROLLING THE SAME, AND METHOD OF MANUFACTURING A SEMICONDUCTOR DEVICE USING THE SAME

(71) Applicants: Jung-min Won, Suwon-si (KR); Myoung-ho Jung, Suwon-si (KR); Byung-soo Moon, Seongnam-si (KR); Sung-kyung Yun, Hwaseong-si (KR); Woo-kyu Lee, Hwaseong-si (KR)

(72) Inventors: Jung-min Won, Suwon-si (KR); Myoung-ho Jung, Suwon-si (KR); Byung-soo Moon, Seongnam-si (KR); Sung-kyung Yun, Hwaseong-si (KR); Woo-kyu Lee, Hwaseong-si (KR)

(21) Appl. No.: 14/870,242

(22) Filed: Sep. 30, 2015

(30) Foreign Application Priority Data
Nov. 7, 2014 (KR) 10-2014-0154736

(51) Int. Cl. H01L 21/687; H01L 21/68; B25J 9/16; G01D 5/34; B25J 9/04; B25J 11/00

(52) U.S. Cl. CPC H01L 21/68707; B25J 9/044; B25J 11/0095; B25J 9/1628; G01D 5/34; H01L 21/681; Y10S 901/02; Y10S 901/15; Y10S 901/46; Y10S 901/09

(57) ABSTRACT

A wafer transfer robot includes a robot transfer mechanism including a robot axis member and a robot arm member connected to the robot axis member, a robot hand connected to the robot arm member of the robot transfer mechanism and configured to transfer a wafer by using the robot transfer mechanism, a vertical displacement sensor installed in an upper side of the robot hand, and a plurality of horizontal displacement sensors installed in the upper side of the robot hand and separate from each other along a virtual line that is perpendicular to bilaterally symmetric axis of the robot hand.

### CROSS-REFERENCE TO RELATED APPLICATION

This application claims the benefit of priority to Korean Patent Application No. 10-2014-0154736, filed on Nov. 7, 2014, in the Korean Intellectual Property Office, the disclosure of which is incorporated herein in its entirety by reference.

### BACKGROUND

Semiconductor chips (semiconductor dies) may be manufactured by performing various fabrication processes, for example, a deposition process, a photolithography process, an etching process, and an electronic die sort (EDS) test process. A semiconductor chip fabrication process may be performed when a wafer transfer robot transfers a wafer into a wafer-mounting chamber, for example, between a cassette and a handling chamber in which semiconductor fabrication processes are performed.

Thus, typically a worker has to check whether a position of a movement operation of the wafer transfer robot is precise. Also, the worker may have to periodically perform a teaching operation in which the position of the movement operation of the wafer transfer robot is previously programmed in a controller.

### SUMMARY

The present disclosure relates to a wafer transfer robot and a method of controlling the same, and more particularly, to a wafer transfer robot in which a teaching operation does not need to be periodically performed, and a method of controlling the wafer transfer robot and manufacturing a semiconductor device using the transfer robot.

Aspects of the inventive concept provide a wafer transfer robot having a robot hand assembly in which a teaching operation does not need to be periodically performed.

Aspects of the inventive concept also provide a method of controlling the wafer transfer robot.

According to an aspect of the inventive concept, there is provided a wafer transfer robot including: a robot transfer mechanism including a robot axis member and a robot arm member connected to the robot axis member; a robot hand connected to the robot arm member of the robot transfer mechanism and for transferring a wafer by using the robot transfer mechanism; a vertical displacement sensor installed in an upper side of the robot hand; and a plurality of horizontal displacement sensors installed in the upper side of the robot hand and separate from each other along a virtual line that is perpendicular to a bilaterally symmetric axis of the robot hand.

The vertical displacement sensor and the plurality of horizontal displacement sensors may be installed to be flush with a top surface of the robot hand.

The vertical displacement sensor may be an integrated light sensor including a first light-emitting portion that radiates first light and a first light-receiving portion that detects the first light.

The horizontal displacement sensors may be installed to be separate from the vertical displacement sensor. The horizontal displacement sensors may include a first horizontal displacement sensor and a second horizontal displacement sensor. The first horizontal displacement sensor may be an integrated light sensor including a second light-emitting portion that radiates second light and a second light-receiving portion that detects the second light, and the second horizontal displacement sensor may be an integrated light sensor including a third light-emitting portion that radiates third light and a third light-receiving portion that detects the third light.

The wafer transfer robot may further include a controller, wherein the controller controls the robot transfer mechanism and the robot hand by using the vertical displacement sensor and the horizontal displacement sensors.

The robot transfer mechanism may be configured to move the robot hand to a wafer-mounting chamber into which a wafer is carried by using the robot transfer mechanism. The plurality of horizontal displacement sensors may be configured to detect a horizontal displacement of the robot hand.

The wafer transfer robot may be further configured to, when the robot hand is carried into the wafer-mounting chamber, radiate first light from a first light-emitting portion of the vertical displacement sensor onto the wafer and detect the first light reflected from the wafer by a first light-receiving portion of the vertical displacement sensor. The vertical displacement sensor may be a light sensor that detects a vertical displacement of the robot hand by using a movement distance of the first light.

The horizontal displacement sensors may include a first horizontal displacement sensor and a second horizontal displacement sensor. The first horizontal displacement sensor and the second horizontal displacement sensor may be disposed at the same distance from a center of the wafer when the robot hand moves to a position in which the robot hand is normally carried into the wafer-mounting chamber. When the robot hand is carried into the wafer-mounting chamber, the first horizontal displacement sensor may include a second light-emitting portion that radiates second light onto the wafer and a second light-receiving portion that detects the second light reflected from the wafer, and when the robot hand is carried into the wafer-mounting chamber, the second horizontal displacement sensor may include a third light-emitting portion that radiates third light onto the wafer and a third light-receiving portion that detects the third light reflected from the wafer.

The horizontal displacement sensors may be light sensors that detect a horizontal displacement of the robot hand by using the second light and the third light that are simultaneously detected.

The wafer-mounting chamber may be a cassette on which the wafer may be mounted, or a handling chamber on which in which semiconductor fabrication processes are performed.

The wafer transfer robot may further include a controller, wherein, when the robot hand is carried into the wafer-mounting chamber, the controller may calculate a vertical displacement error and a horizontal displacement error of the injected robot hand with respect to the position in which the robot hand is normally carried into the wafer-mounting chamber, based on the vertical displacement and the horizontal displacement of the robot hand detected by the vertical displacement sensor and the horizontal displacement sensors, and the calculated vertical displacement error and horizontal displacement error may be reflected in position parameters of the robot transfer mechanism.

According to certain aspects of the inventive concept, a wafer transfer robot includes: a robot transfer mechanism including a robot axis member and a robot arm member connected to the robot axis member; a robot hand connected to the robot arm member of the robot transfer mechanism and configured to move to a wafer-mounting chamber into which a wafer is carried by using the robot transfer mechanism; a vertical displacement sensor installed in an upper side of the robot hand and configured to detect a vertical displacement of the robot hand when the robot hand moves into the wafer-mounting chamber; a plurality of horizontal displacement sensors installed in the upper side of the robot hand and separate from each other along a virtual line that is perpendicular to a movement direction of the robot hand when moving into the wafer-mounting chamber and configured to detect a horizontal displacement of the robot hand when the robot hand moves into the wafer-mounting chamber; and a controller configured to calculate a vertical displacement error and a horizontal displacement error of the robot hand that is normally carried into the wafer-mounting chamber when the robot hand moves into the wafer-mounting chamber, and configured to correct position parameters of the robot transfer mechanism based on the calculated vertical displacement error and horizontal displacement error and to interlock the robot transfer mechanism.

The vertical displacement sensor may be a light sensor including a first light-emitting portion that radiates first light onto the wafer and a first light-receiving portion that detects the first light reflected from the wafer, wherein the controller is configured to detect a vertical displacement of the robot hand by using a movement distance of the first light.

The plurality of horizontal displacement sensors may include a first horizontal displacement sensor and a second horizontal displacement sensor, and the first horizontal displacement sensor may include a second light-emitting portion that radiates second light onto the wafer and a second light-receiving portion that detects the second light reflected from the wafer, and the second horizontal displacement sensor may include a third light-emitting portion that radiates third light onto the wafer and a third light-receiving portion that detects the third light reflected from the wafer, and the horizontal displacement sensors may be light sensors that detect a horizontal displacement of the robot hand by using the second light and the third light that are simultaneously detected.

Position parameters of the robot transfer mechanism may be vertical position coordinates, forward/backward position coordinates, left/right position coordinates, or a rotation angle of the robot hand.

According to certain aspects of the inventive concept, a method of controlling a wafer transfer robot includes: starting moving a robot hand assembly including a robot hand connected to a robot transfer mechanism toward an outer edge of a wafer in a wafer-mounting chamber, wherein the robot hand includes, a vertical displacement sensor installed in a front upper portion of the robot hand and horizontal displacement sensors installed in a rear upper portion of the robot hand and separate from each other along a virtual line that is perpendicular to the movement direction of the robot hand; correcting position parameters of the robot transfer mechanism by detecting a vertical displacement of the robot hand with respect to the wafer by using the vertical displacement sensor as a part of the robot hand is moved into the wafer-mounting chamber; correcting the position parameters of the robot transfer mechanism by detecting a horizontal displacement of the robot hand with respect to the wafer by using the horizontal displacement sensors as the robot hand is further moved into the wafer-mounting chamber; and finishing the moving of the robot hand with respect to the wafer in the wafer-mounting chamber by the robot hand.

The vertical displacement sensor may include a first light-emitting portion that radiates first light onto the wafer and a first light-receiving portion that detects the first light reflected from the wafer, and the vertical displacement may be detected based on a time interval between a time that the first light is radiated and a time that the first light is detected, or a phase difference.

The horizontal displacement sensors may include a first horizontal displacement sensor and a second horizontal displacement sensor that is separate from the first horizontal displacement sensor, and the first horizontal displacement sensor may include a second light-emitting portion that radiates second light onto the wafer and a second light-receiving portion that detects the second light reflected from the wafer, and the second horizontal displacement sensor may include a third light-emitting portion that radiates third light onto the wafer and a third light-receiving portion that detects the third light reflected from the wafer, and the horizontal displacement may be detected based on a time when the horizontal displacement sensors detect the second light and the third light simultaneously.

A position where moving of the robot hand is finished, when the horizontal displacement of the robot hand is detected by using the horizontal displacement sensors, may be a position where the second light and the third light are simultaneously detected when the robot hand proceeds along a central line of the wafer.

Horizontal flatness of the robot hand may be controlled by comparing a light-receiving amount of the first light-receiving portion of the vertical displacement sensor, a light-receiving amount of the second light-receiving portion of the first horizontal displacement sensor, and a light-receiving amount of the second horizontal displacement sensor.

Position parameters of the robot transfer mechanism, corrected by detecting the vertical displacement, may be vertical position coordinates of the robot hand.

Position parameters of the robot transfer mechanism, corrected by detecting the horizontal displacement, may be forward/backward position coordinates, left/right position coordinates, and a rotation angle of the robot hand.

The correcting of the position parameters of the robot transfer mechanism by detecting the vertical displacement and the horizontal displacement may include: calculating a vertical displacement error and a horizontal displacement error of the robot hand with respect to a position where the robot hand was previously set to be moved; and correcting the position parameters of the robot transfer mechanism based on the calculated vertical displacement error and horizontal displacement error.

The correcting of the position parameters of the robot transfer mechanism by detecting the vertical displacement and the horizontal displacement may be continuously performed from a time when the robot hand starts reaching the outer edge of the wafer in the wafer-mounting chamber to a time when at least the horizontal displacement sensors move past the outer edge of the wafer in the wafer-mounting chamber.

Determining whether moving of the robot hand is finished may be performed when the vertical displacement has a predetermined value.

The method may additionally include using the robot hand, removing the wafer from the wafer-mounting chamber; using the robot hand, placing the wafer in a processing equipment device; performing a fabrication process on the wafer in the processing equipment device; and after performing the fabrication process, forming a semiconductor device using one or more singulated chips from the wafer.

According to certain aspects of the disclosed embodiments, a method includes: performing a first fabrication process on a wafer in a first processing equipment device; moving the wafer from the first processing equipment device to a cassette; performing an alignment procedure for a robot hand of a robot arm with respect to the wafer in the cassette; using the robot hand, moving the wafer from the cassette to a second processing equipment; performing a second fabrication process on the wafer in the second processing equipment device to form a plurality of semiconductor chips on the wafer; and singulating the plurality of semiconductor chips from the wafer. The alignment procedure includes: using a plurality of sensor devices on a surface of the robot hand to determine if the robot hand is at a desired height, is aligned to be centered with respect to the wafer, and is flat with respect to the wafer; and based on the determination, performing an alignment for the robot hand.

The method may further comprise packaging the plurality of chips into a plurality of semiconductor packages.

The plurality of sensor devices may include at least two sensors equidistant from a bilateral center of the robot hand, wherein the alignment procedure further includes determining whether the robot hand is aligned to be centered with respect to the wafer and whether the robot hand is flat with respect to the wafer using the two sensors.

The plurality of sensor devices may include at least a third sensor used to determine whether the robot hand is at the desired height with respect to the wafer.

The alignment procedure may further include: starting moving the robot hand toward an outer edge of the wafer in the cassette, and correcting position parameters of a robot transfer mechanism that controls the robot arm and robot hand by detecting a horizontal displacement of the robot hand with respect to the wafer by using the two sensors as the robot hand is further moved past the outer edge of the wafer.

### BRIEF DESCRIPTION OF THE DRAWINGS

Exemplary embodiments of the inventive concept will be more clearly understood from the following detailed description taken in conjunction with the accompanying drawings in which:

FIG. 1 is a perspective view of a wafer transfer robot according to certain exemplary embodiments;

FIG. 2 is a plan view of the wafer transfer robot illustrated in FIG. 1, according to certain exemplary embodiments;

FIGS. 3A through 3C are views of an operation of the wafer transfer robot of FIGS. 1 and 2, according to certain exemplary embodiments;

FIGS. 4A and 4B are views of a robot hand assembly of a wafer transfer robot, according to certain exemplary embodiments;

FIGS. 5A and 5B are respectively a perspective view and a side view of a movement operation of a robot hand by using the wafer transfer robot of FIG. 1, according to certain exemplary embodiments;

FIGS. 6A and 6B are diagrams of a configuration and control of the wafer transfer robot of FIG. 1, according to certain exemplary embodiments;

FIGS. 7A through 7C are views of an operation of detecting a vertical displacement and a horizontal displacement of the robot hand with respect to a wafer by using a robot hand and displacement sensors according to certain exemplary embodiments;

FIGS. 8 through 10 are views of a horizontal displacement of a robot hand with respect to the wafer by using the movement operation of the robot hand according to certain exemplary embodiments;

FIGS. 11 through 13 are plan views of an operation of correcting a horizontal displacement of the robot hand with respect to a wafer when the robot hand is carried into a cassette, according to certain exemplary embodiments;

FIG. 14 is a view of a correction content of the robot hand of the controller according to operation signals of displacement sensors, according to certain exemplary embodiments;

FIG. 15 is a flowchart of a method of controlling a wafer transfer robot by using the robot hand assembly having displacement sensors, according to certain exemplary embodiments;

FIG. 16 is a flowchart of a method of controlling a wafer transfer robot by using the robot hand assembly having displacement sensors, according to certain exemplary embodiments;

FIG. 17 is a view of the relationship between arrangements of elements of a wafer handling system including a wafer transfer robot, according to certain exemplary embodiments;

FIG. 18 is a schematic view of the wafer handling system illustrated in FIG. 17, according to certain exemplary embodiments;

FIG. 19 is a configuration view of an example of the wafer handling system including the wafer transfer robot illustrated in FIG. 17, according to certain exemplary embodiments;

FIG. 20 is a schematic view of a prober and the wafer transfer robot of FIG. 19, according to certain exemplary embodiments;

FIG. 21 is a block diagram of a schematic configuration of the wafer transfer robot of FIG. 20, according to certain exemplary embodiments; and

FIG. 22 is a configuration view of a wafer handling system including a wafer transfer robot, according to certain exemplary embodiments.

FIG. 23 is a flow chart describing a method of manufacturing a semiconductor device using a wafer transfer robot, according to certain exemplary embodiments.

In the drawings, the size and relative sizes of various components and regions may be exaggerated for convenience and clarity. Like numbers refer to like elements throughout. Though the different figures show variations of exemplary embodiments, these figures are not necessarily intended to be mutually exclusive from each other. Rather, as will be seen from the context of the detailed description below, certain features depicted and described in different figures can be combined with other features from other figures to result in various embodiments, when taking the figures and their description as a whole.

### DETAILED DESCRIPTION

Exemplary embodiments of the present invention will be described more fully with reference to the accompanying drawings. The present invention may, however, be embodied in many different forms and should not be construed as being limited to the exemplary embodiments set forth herein.

It will be understood that when an element, such as a layer, a region, or a wafer (substrate) is referred to as being “on”, “connected to”, or “coupled to” another element, it can be directly “on”, “connected to”, or “coupled to” the other element or intervening elements may be present therebetween. In contrast, when an element is referred to as being “directly on”, “directly connected to”, or “directly coupled to” another element, or as “contacting” another element, there are no intervening elements present. As used herein, the term “and/or” includes any and all combinations of one or more of the associated listed items.

It will be understood that, although the terms “first”, “second”, “third”, etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section. Thus, a first element, component, region, layer or section discussed below in one section of the specification could be termed a second element, component, region, layer or section in another section of the specification, without departing from the teachings of the example embodiment. In addition, in certain cases, even if a term is not described using “first,” “second,” etc., in the specification, it may still be referred to as “first” or “second” in a claim in order to distinguish different claimed elements from each other.

Also, relative terms, such as “on” or “above” and “under” or “below”, may be used herein, for the purpose of describing the relationship between some elements with respect to other elements, as illustrated in the drawings. The relative terms may be understood to intend to include other directions of an element in addition to a direction illustrated in the drawings. For example, when the element is switched in opposite position in the drawings, elements described to be disposed on top surfaces of other elements have directions on bottom surfaces of the other elements. Thus, the term “on” may include all of directions “under” and “on” depending on a particular direction in the drawings. When an element is directed in another direction (90 degree rotation with respect to another direction), relative descriptions used herein may be interpreted accordingly.

The terminology used herein is used to describe particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Terms such as “same,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning.

Hereinafter, exemplary embodiments of the present invention will be described with reference to accompanying drawings schematically illustrating the embodiments. In the drawings, for example, illustrated shapes may be deformed according to fabrication technology and/or tolerances. Therefore, the exemplary embodiments of the present invention are not limited to certain shapes illustrated in the present specification, and may include modifications of shapes caused in fabrication processes. The following embodiments may be configured of one embodiment or a combination of a plurality of embodiments.

Hereinafter, a configuration of a wafer transfer robot will be described. Since the shape of the wafer transfer robot may differ, the present specification suggests a wafer transfer robot according to certain exemplary embodiments, and the inventive concept is not limited thereto.

Furthermore, a procedure of an operation of the wafer transfer robot will be described. The procedure of the operation of the wafer transfer robot may be related to a teaching operation in which a worker previously programs a position of a movement operation of the wafer transfer robot in a controller. The procedure of the operation of the wafer transfer robot may be performed in various ways but will now be described only for an illustrative purpose.

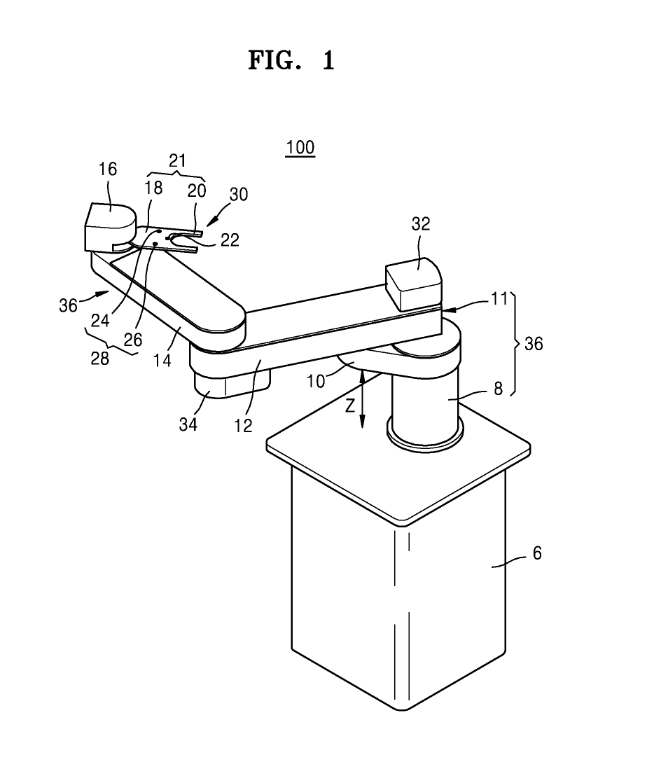

FIG. 1 is a perspective view of a wafer transfer robot 100 according to an exemplary embodiment of the inventive concept.

In detail, the wafer transfer robot 100 may include a robot transfer mechanism 36 including a robot axis member 8 and a robot arm member 11, and a robot hand assembly 30 including a robot hand 21 and vertical and horizontal displacement sensors 22 and 28. The robot arm member 11 may be connected to the robot axis member 8. The robot hand assembly 30 may be connected to the robot arm member 11. Thus, the robot hand assembly 30 including the robot hand 21 and the vertical and horizontal displacement sensors 22 and 28 may be connected to the robot transfer mechanism 36.

The robot axis member 8 may be coupled to a robot body 6. The robot arm member 11 connected to the robot axis member 8 may have a multi joint shape. The robot arm member 11 may include a first arm 10, a second arm 12, a third arm 14, and a fourth arm 16. In certain sections of this specification, the robot arm member 11 may be referred to as a robot arm 11, and first arm 10, second arm 12, third arm 14, and fourth arm 16 may be referred to as first arm segment 10, second arm segment 12, third arm segment 14, and fourth arm segment 16.

The robot axis member 8 may be coupled to a bottom surface of one end of the first arm 10 so as to lift/lower the first arm 10 and rotate the first arm 10, for example using one or more actuators, motors, hydraulic devices, etc. The first arm 10 and the robot axis member 8 may be separately formed. In some cases, the first arm 10 and the robot arm member 8 may be integrally formed. When the first arm 10 and the robot arm member 8 are integrally formed, the first arm 10 and the robot axis member 8 may be simultaneously rotated.

The second arm 12 may be coupled to the other end of the first arm 10, which is an opposite end to the one end coupled to the robot axis member 8. Accommodation portions 32 and 34 may be disposed on the second arm 12 so as to accommodate a driving unit, which may include, for example, one or more actuators, motors, etc. The third arm 14 may be coupled to an end of the second arm 12. The fourth arm 16 may be coupled to an end of the third arm 14.

The robot hand 21 may be mounted on the fourth arm 16, and may be part of the robot hand assembly 30 so as to lift and support a wafer and transfer the wafer by using the robot transfer mechanism 36. The robot hand 21 may include a body portion 18 and a finger portion 20. A vacuum inlet (not shown) may be included in the finger portion 20 so that the wafer may be mounted on and fixed to the finger portion 20 through the vacuum inlet (not shown).

The vertical displacement sensor 22 and the horizontal displacement sensors 28 may be installed at the body portion 18 of the robot hand 21 so as to respectively detect a vertical displacement and a horizontal displacement of the robot hand 21 with respect to the wafer. The robot hand 21, the vertical displacement sensor 22, and the horizontal displacement sensors 28 constitute the robot hand assembly 30. The horizontal displacement sensors 28 may include a first horizontal displacement sensor 24 and a second horizontal displacement sensor 26. The vertical displacement sensor 22 and the first and second horizontal displacement sensors 24 and 26 will be described later in detail.

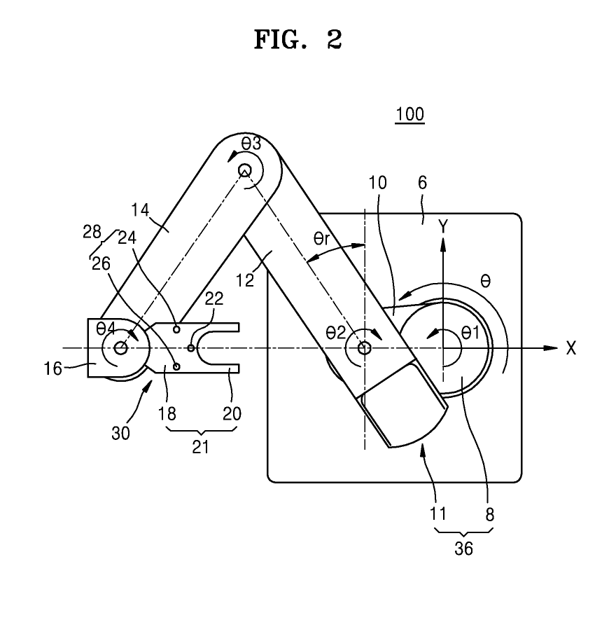

FIG. 2 is an exemplary plan view of the wafer transfer robot 100 illustrated in FIG. 1.

In detail, the robot hand 21 of the wafer transfer robot 100 may move in four directions. The robot hand 21 of the wafer transfer robot 100 may move in a direction in which the robot hand 21 protrudes from the fourth arm 16, that is, in an X-direction, in a Y-direction that is perpendicular to the X-axis, in a direction θ in which the robot arm member 11, i.e., all of the first, second, third, and fourth arms 10, 12, 14, and 16 are rotated, and in a Z-direction in which the robot axis member 8 moves in a vertical direction along a Z-axis of FIG. 1.

Movement of the robot hand 21 along the X-axis may be defined as a forward/backward operation, and movement of the robot hand 21 along the Y-axis may be defined as a left/right operation, and rotation θ may be defined as a rotation operation. An angle of each of the first arm 10 and the third arm 14 of the wafer transfer robot 100 may be defined based on an angle at which the first arm 10 and the third arm 14 are rotated counterclockwise, and an angle of each of the second arm 12 and the fourth arm 16 of the wafer transfer robot 100 may be defined based on an angle at which the second arm 12 and the fourth arm 16 are rotated clockwise. This is merely to define an angle but does not mean that each of the first, second, third, and fourth arms 10, 12, 14, and 16 is rotated only in a direction as above-described.

Based on the above-described rotation directions, a rotation angle of the first arm 10 may be defined as θ₁, and a rotation angle of the second arm 12 may be defined as θ₂, and a rotation angle of the third arm 14 may be defined as θ₃, and a rotation angle of the fourth arm 16 may be defined as θ₄. An angle formed between the second arm 12 and the Y-axis in a basic position, i.e., in a home position, may be defined as Or. This may be an angle with respect to the Y-axis that the second arm 12 returns to after completing a transfer operation. For example, this angle may be a position that the second arm 12 is in with respect to the Y-axis when not in use, when in a standby mode, or between transfer operations.

As illustrated in FIGS. 1 and 2, all of the first, second, third, and fourth arms 10, 12, 14, and 16 may move in the vertical direction. Movement of the first, second, third, and fourth arms 10, 12, 14, and 16 along the Z-axis may be defined as movement in the Z-direction. This operation may be performed by lifting/lowering the robot axis member 8 regardless of the operation of the first, second, third, and fourth arms 10, 12, 14, and 16. Movement in the Z-direction may be performed by a driving unit (not shown) disposed in the robot body 6. Movement in the Z-direction may be performed separately from or together with movement of the first, second, third, and fourth arms 10, 12, 14, and 16. Movement along the Z-axis may be defined as a vertical operation of the robot hand 21.

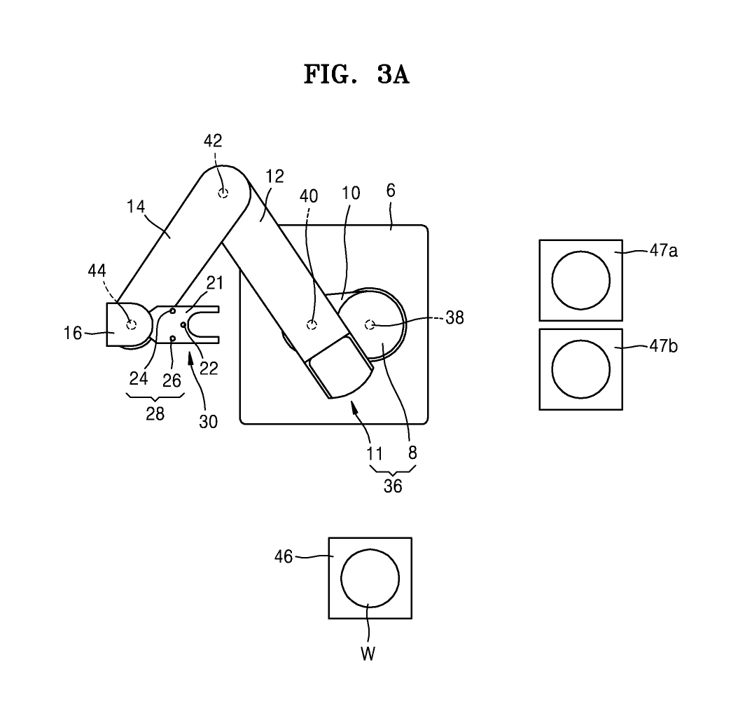

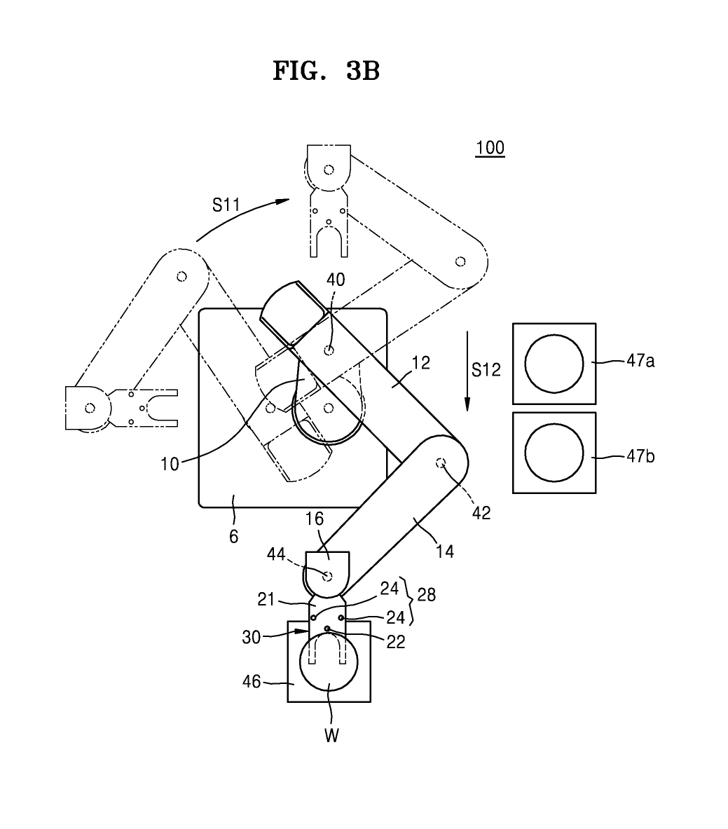

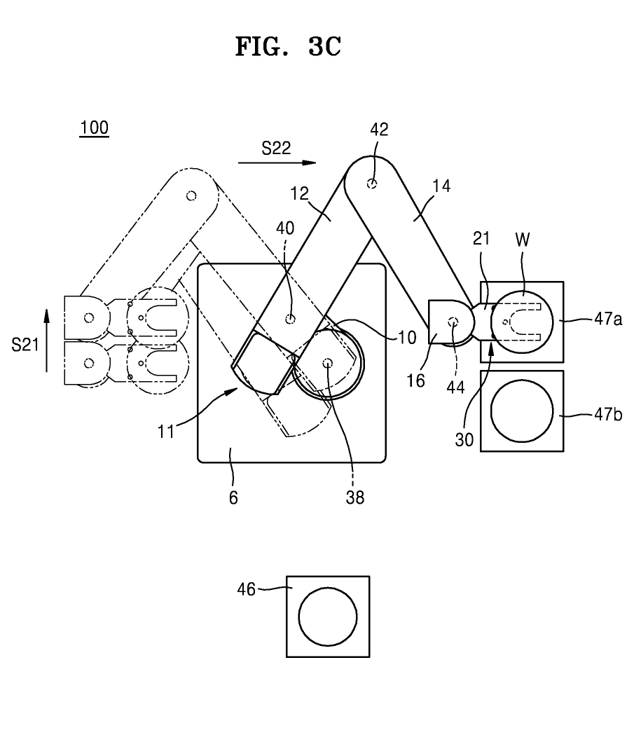

FIGS. 3A through 3C are exemplary views of an operation of the wafer transfer robot 100 of FIGS. 1 and 2.

FIG. 3A is a view of a basic position of the wafer transfer robot 100, i.e., a home position.

As illustrated in FIG. 3A, wafer-mounting chambers 46, 47a, and 47b on which a wafer W may be mounted, may be disposed around the wafer transfer robot 100. Hereinafter, the wafer-mounting chamber 46 is referred to as a cassette on which the wafer W may be mounted, and hereinafter, the wafer-mounting chambers 47a and 47b are referred to as first and second handling chambers on which the wafer W is mounted and a semiconductor fabrication process is performed. The first and second handling chambers 47a and 47b may be fabrication chambers, for example, for performing processes such as etching, layer depositing, ion implantation, and other fabrication processes. Although the drawings illustrate an example of arrangement of the wafer transfer robot 100, the cassette 46 and the first and second handling chambers 47a and 47b, they may be freely arranged in different manners.

The first handling chamber 47a and the second handling chamber 47b may be disposed to be parallel to each other in the same direction based on the wafer transfer robot 100. The wafer transfer robot 100 may move when the position shown in FIG. 3A is set to a basic position, i.e., a home position and the home position is set to a starting point. The basic position shown in the drawing is also one example, and a different position may be set to the basic position. In FIG. 3A, reference numerals 38, 40, 42, and 44 may refer to rotation shafts.

FIG. 3B is a view of an exemplary operation of taking the wafer W off of the cassette 46 on which the wafer W is stacked.

As illustrated in FIG. 3B, the cassette 46 is disposed in a different direction from the direction in which the robot hand 21 is directed, from the basic position. Thus, an operation in which the robot hand 21 is directed toward the cassette 46 is first performed and then, an operation in which the robot hand 21 moves toward the cassette 46 is performed.

In first Operation S11, a rotation operation of the robot hand 21 is performed. The rotation operation may be an operation in which only the first arm 10 is rotated about a first rotation shaft 38, as described above. The first arm 10 may be rotated at an appropriate angle so that the robot hand 21 may be directed toward the cassette 46.

In second Operation S12, a left/right operation of the robot hand 21 is performed. The left/right operation of the robot hand 21 refers to an operation in which, when the robot hand 21 is directed toward the cassette 46 via the rotation operation, the robot hand 21 moves toward the cassette 46. The left/right operation may be an operation in which the first arm 10 is fixed and the second arm 12, the third arm 14, and the fourth arm 16 are rotated. In order to optimize rotation angles of the first, second, third, and fourth arms 10, 12, 14, and 16 and a transfer path of the wafer W, in some embodiments, lengths of the second arm 12 and the third arm 14 may be different than shown in FIG. 3B.

In this way, when the robot hand 21 is carried into the cassette 46, the wafer W is mounted on the robot hand 21. If the wafer W is mounted on the robot hand 21, the wafer transfer robot 100 may be returned to its basic position by reversely performing the above-described operations. For example, the left/right operation that is second Operation S22 may be performed, and the rotation operation that is first Operation S11 may be performed so that the wafer transfer robot 100 may be returned to its basic position. It should be noted that although the operations S11 and S12 are depicted and described separately and as occurring consecutively, in some embodiments, these steps may occur at least in part at the same time. After the wafer transfer robot 100 is returned to its basic position in a state in which the wafer W is mounted on the robot hand 21, an operation of transferring the wafer W to the first and second handling chambers 47a and 47b may be performed.

FIG. 3C is a view of an operation of transferring the wafer W to the first handling chamber 47a.

As illustrated in FIG. 3C, the first handling chamber 47a in the basic position is arranged in the X-direction with respect to the robot hand 21. However, the position of the first handling chamber 47a is not in the same line as the position of the robot hand 21. Thus, in certain embodiments, an operation in which the robot hand 21 is disposed in the same line as the first handling chamber 47a is first performed, and an operation in which the robot hand 21 moves toward the first handling chamber 47a is performed. These may be performed at least partly in an overlapping manner.

In first Operation S21, the left/right operation of the robot hand 21 is performed. The left/right operation is an operation in which all of the first, second, third, and fourth arms 10, 12, 14, and 16 are rotated, as described above. By using the left/right operation, the robot hand 21 may move along the Y-axis, and thus the robot hand 21 may be disposed in the same line as the first handling chamber 47a. In certain embodiments, in the left/right operation, the first arm 10 and the third arm 14 may be rotated clockwise, and the second arm 12 and the fourth arm 16 may be rotated counterclockwise.

In second Operation S22, the forward/backward operation is performed. The forward/backward operation is an operation in which the robot hand 21 moves toward the first handling chamber 47a. The forward/backward operation is an operation in which the first arm 10 is fixed and the second arm 12, the third arm 14, and the fourth arm 16 are rotated.

When the robot hand 21 is carried into the first handling chamber 47a in this way, the wafer W mounted on the robot hand 21 may be mounted in the first handling chamber 47a. After the wafer W is mounted in the first handling chamber 47a, the wafer transfer robot 100 may be returned to its basic position. This is done by reversely performing the above-described operations. For example, the forward/backward operation that is second Operation S22 is performed, and the left/right operation that is first Operation S21 is performed. It should be noted that although the operations S21 and S22 are depicted and described separately and as occurring consecutively, in some embodiments, these steps may occur at least in part at the same time.

Vertical displacement and horizontal displacement of the robot hand 21 may be defined as below depending on a state of an operation of the robot hand 21.

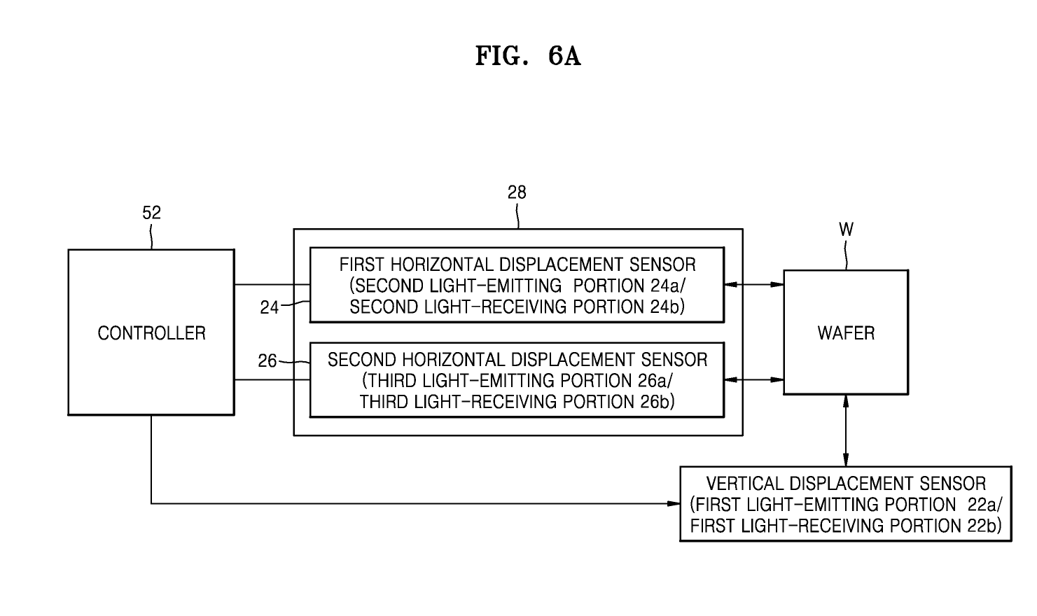

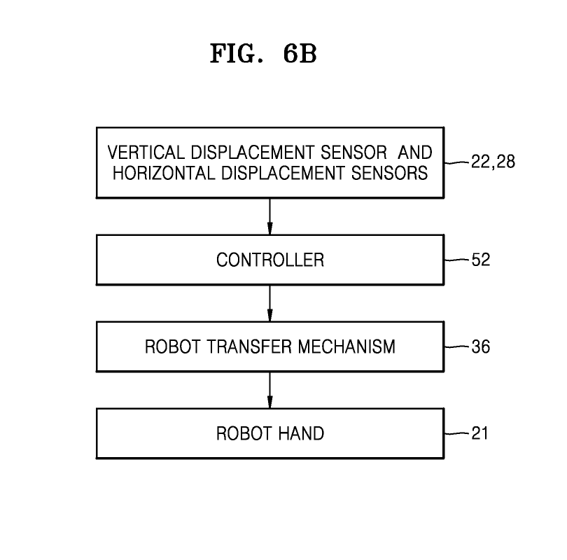

The vertical displacement of the robot hand 21 may refer to a distance value at which the robot hand 21 moves in the Z-axis direction (vertical operation direction). The vertical displacement of the robot hand 21 may also refer to a Z-direction setting value of the robot hand 21 that is set in a controller (52 of FIGS. 6A and 6B) of the wafer transfer robot 100.

The horizontal displacement of the robot hand 21 may refer to a distance value at which the robot hand 21 moves in the X-axis direction (forward/backward operation direction) and the Y-axis direction (left/right operation direction). The horizontal displacement of the robot hand 21 may also refer to an X-direction (forward/backward operation direction) setting value and a Y-direction (left/right operation direction) setting value that are set in the controller (52 of FIGS. 6A and 6B) of the wafer transfer robot 100.

Typically, a wafer transfer robot periodically performs a teaching operation in which the worker initially and then periodically programs a position of the movement operation of the wafer transfer robot, i.e., the horizontal displacement and the vertical displacement in a controller.

However, the wafer transfer robot 100 according to certain embodiments of the inventive concept does not need to periodically perform the teaching operation, because it may automatically detect, set, and correct the horizontal displacement and the vertical displacement of the robot hand 21 by using the vertical displacement sensor 22 and the horizontal displacement sensors 28 installed at the robot hand 21. Detecting the horizontal displacement and the vertical displacement of the robot hand 21 will be described later in detail.

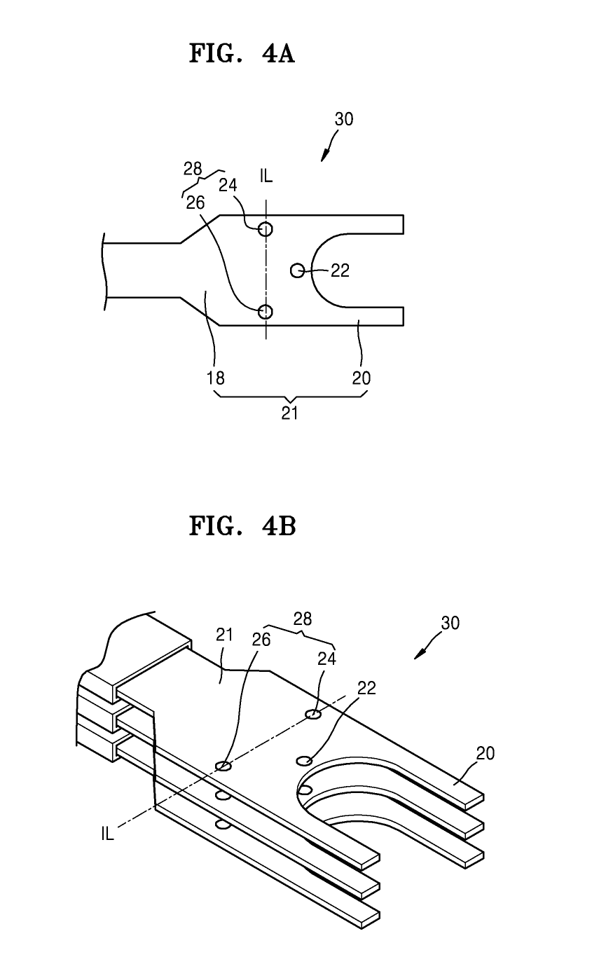

FIGS. 4A and 4B are views of a robot hand assembly 30 of a wafer transfer robot, according to certain exemplary embodiments.

In detail, FIG. 4A is a plan view of the robot hand assembly 30, which illustrates that the robot hand assembly 30 may transfer one wafer, and FIG. 4B is a perspective view of the robot hand assembly 30, which illustrates that the robot hand assembly 30 may transfer a plurality of wafers. Hereinafter, for convenience, one robot hand assembly 30 will be described.

The robot hand assembly 30 may include the robot hand 21 and the vertical and horizontal displacement sensors 22 and 28, as described above. The robot hand 21 may include the body portion 18 and the finger portion 20, which may also be referred to as a base portion 18 and a handling portion 20. The vertical displacement sensor 22 may be installed in an upper side of the robot hand 21, for example, at an upper surface of the robot hand 21. The vertical displacement sensor 22 may detect the vertical displacement of the robot hand 21 with respect to the wafer W. Detecting the vertical displacement will be described later in detail.

The horizontal displacement sensors 28 may be installed in the upper side of the robot hand 21, for example, at an upper surface of the robot hand 21, and separate from each other along a virtual line IL that is perpendicular to a movement direction of the robot hand 21. This movement direction of the robot hand, in certain situations, may be the movement direction of the robot hand 21 within a cassette 46 or handling chamber 47a or 47b. For example, it may refer to a movement direction in the x or y direction of the robot hand 21 starting at the time a first portion of a finger portion 20 of the robot hand 21 respectively enters a handling chamber 47a/47b or a cassette 46, and continuing as the robot hand 21 further moves into the handling chamber 47a/47b or cassette 46. For example, the virtual line IL may be perpendicular to a movement direction of the robot hand 21 in the x direction when the robot hand 21 is symmetrically arranged along a line parallel to the x direction. The virtual line IL may also be perpendicular to a movement direction of the robot hand 21 in the y direction when the robot hand 21 is symmetrically arranged along a line parallel to the y direction. The virtual line IL may also be described as a line tangent to an arc formed by rotation of the fourth arm 16 about the third arm 14, at a point along a line extending between vertical displacement sensor 22 and rotation shaft 44, which rotation shaft 44 may form an axis of rotation between the fourth arm 16 and the third arm 14. Also, as depicted for example in FIGS. 4A and 4B, the horizontal displacement sensors 24 and 26 may be located along a virtual line that is perpendicular to a bilaterally symmetric axis of the robot hand. The horizontal displacement sensors 28 may be equidistant from the bilaterally symmetric axis. The horizontal displacement sensors 28 may be installed to be separate from the vertical displacement sensor 22. The horizontal displacement sensors 28 may include a first horizontal displacement sensor 24 and a second horizontal displacement sensor 26. The horizontal displacement sensors 28 may detect the horizontal displacement of the robot hand 21 with respect to the wafer W. Detecting the horizontal displacement will be described later in detail.

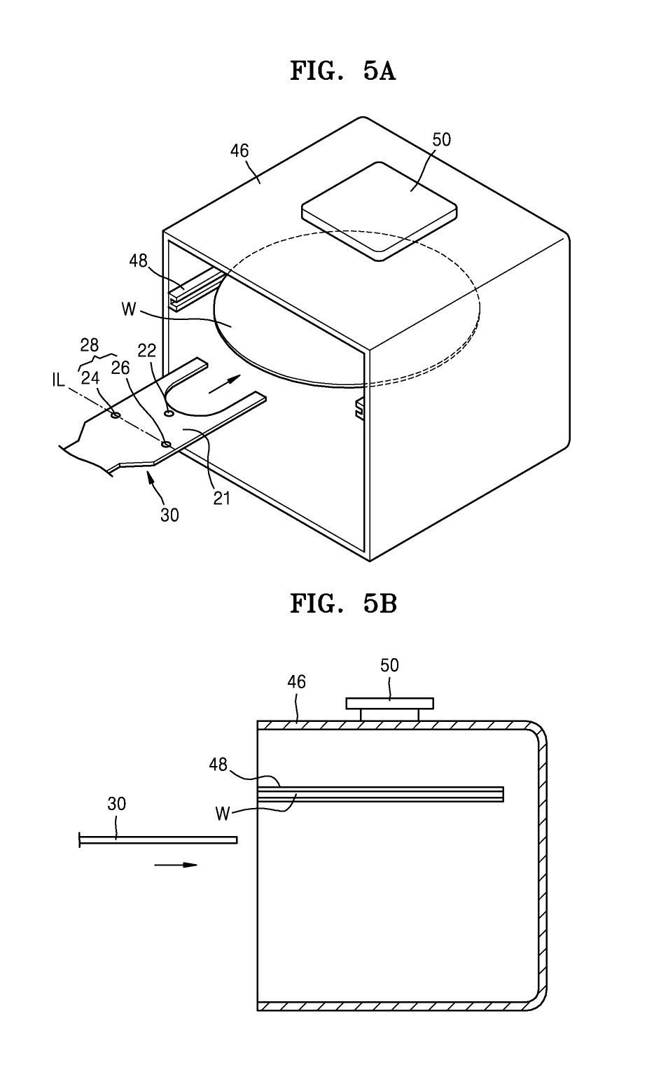

FIGS. 5A and 5B are respectively an exemplary perspective view and an exemplary side view of a movement operation of a robot hand by using the wafer transfer robot of FIG. 1.

In detail, the robot hand 21, on which the horizontal displacement sensors 28 are mounted, and thus, the robot hand assembly 30, may move toward the cassette 46 that is a wafer-mounting chamber into which or from which a wafer W is carried. The cassette 46 may be a wafer cassette that is referred to as front opening unified pod (FOUP) having a front side in which an opening is formed.

The cassette 46 may be provided as a container having an overall hexahedral shape, the rear (opposite direction to a side in which the opening is formed) of which has a circular or an oval shape when viewed from an overhead direction. A holding member 50 (also referred to as a cassette holder) that is used to hold the cassette 46 by using a cassette transfer device, such as an overhead shuttle (OHS), may be disposed on a top surface of the cassette 46.

As described above, the opening may be formed in the front side of the cassette 46. The opening may have a rectangular shape. Through the opening, the wafer W may be carried into the cassette 46 or out of the cassette 46 by using the robot hand assembly 30. FIGS. 5A and 5B illustrate a state in which the wafer W is carried into the cassette 46, for convenience of explanation.

A support member 48 may be formed on an internal surface of the cassette 46. The support member 48 may be provided to have a shape of a bracket or slot formed along a circumference of the other sides except for the front side of the cassette 46 as seen from above. The support member 48 may be referred to as a support rail, support bracket, or support slot.

A plurality of support members 48 may be disposed in the cassette 46 to be separate by a predetermined distance from each other in the vertical direction so that a plurality of wafers W may be accommodated in the cassette 46. For example, 25 support members (slots) may be formed in the cassette 46 so as to accommodate 25 wafers W. However, FIGS. 5A and 5B illustrate only one support member 48 for convenience of explanation.

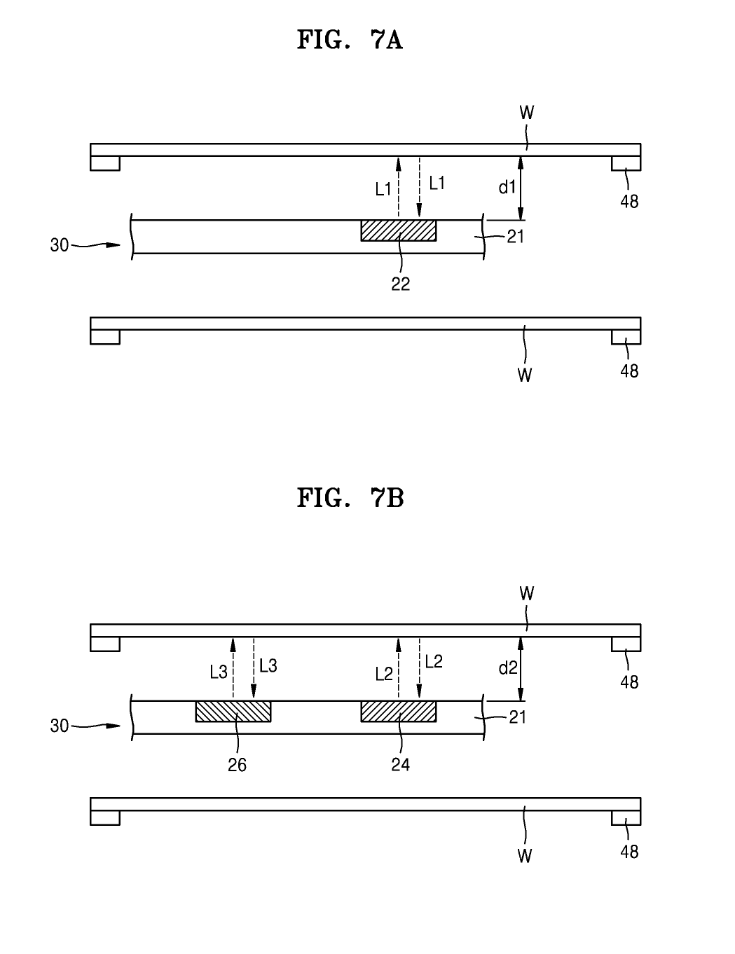

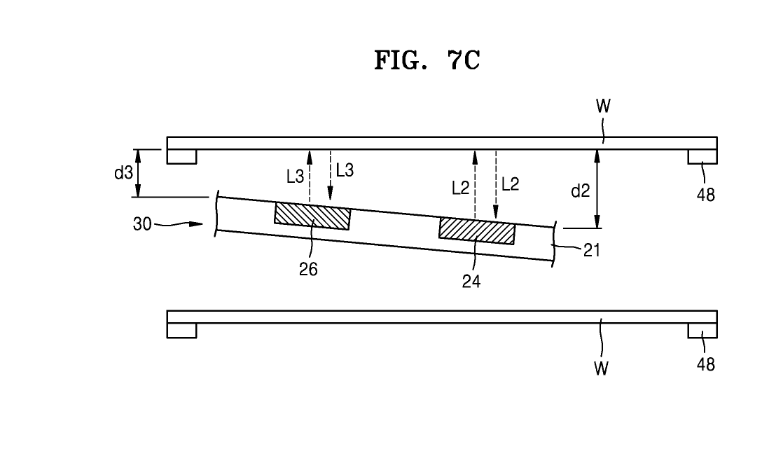

FIGS. 6A and 6B are exemplary block diagrams of a configuration and control of the wafer transfer robot 100 of FIG. 1, and FIGS. 7A through 7C are views of an operation of detecting vertical displacement and horizontal displacement of a robot hand with respect to a wafer by using the robot hand and displacement sensors according to certain exemplary embodiments.

In detail, the wafer transfer robot (100 of FIG. 1) may include the vertical displacement sensor 22, the horizontal displacement sensors 28, and the controller 52. As described above with reference to FIGS. 5A and 5B, the robot hand 21, on which the vertical and horizontal displacement sensors 22 and 28 are mounted, and thus the robot hand assembly 30, may be moved into a wafer-mounting chamber into which the wafer W is disposed, i.e., into the cassette 46. In this way, as illustrated in FIGS. 7A through 7C, the robot hand 21, on which the vertical and horizontal displacement sensors 22 and 28 are installed, may be disposed between the wafers W mounted on the support member 48.

The vertical displacement sensor 22 may be installed in the upper side of the robot hand 21. For example, when the thickness of the robot hand 21 is several millimeters, the thickness of the vertical displacement sensor 22 may be less than the thickness of the robot hand 21. A top surface of the vertical displacement sensor 22 may be flush (e.g., coplanar) with a top surface of the robot hand 21.

The vertical displacement sensor 22 may measure the vertical displacement of the robot hand 21 with respect to the wafer W mounted on the support member 48 when the robot hand 21 is carried into the cassette (46 of FIGS. 5A and 5B) that is the wafer-mounting chamber. The vertical displacement sensor 22 may be, for example, an integrated light sensor including a first light-emitting portion 22a that radiates first light L1 and a first light-receiving portion 22b that detects (receives) the first light L1, as illustrated in FIGS. 6A and 7A. In certain embodiments, the first light L1 may be laser light. The first light-emitting portion 22a may be, for example, a laser diode (LD) that emits laser, and the first light-receiving portion 22b may be, for example, a photodiode (PD) that detects (receives) laser.

When the first light-emitting portion 22a emits the first light L1 onto the wafer W, the first light L1 may be reflected from the wafer W, and the first light-receiving portion 22b may detect (receive) the reflected first light L1. When the vertical displacement sensor 22 is used, a separation distance d1 between a top surface of the robot hand 21 and a bottom surface of the wafer W may be measured. Thus, the vertical displacement of the robot hand 21 that constitutes the wafer transfer robot 100 of FIGS. 1 and 2 may be measured.

In more detail, time-of-flight (TOF) of light may be used to measure a distance by reflecting light, such as laser. Since the speed of light is constant, the distance may be measured by knowing the TOF. Also, TOF may be calculated from a time interval between the time that light is directly emitted and the time that the light is received, or from a phase difference between the emitted light and the received light.

TOF of the first light L1 that is detected (received) by the first light-receiving portion 22b and is emitted may be calculated, and a movement distance of the first light L1 may be obtained from the TOF. As a result, the vertical displacement that corresponds to vertical movement displacement of the robot hand 21 that constitutes the wafer transfer robot 100 may be obtained based on the movement distance.

The horizontal displacement sensors 28 may be installed in the upper side of the robot hand 21. For example, when the thickness of the robot hand 21 is several millimeters, the thicknesses of the horizontal displacement sensors 28 may be less than the thickness of the robot hand 21. The horizontal displacement sensors 28 may be flush (e.g., coplanar) with the top surface of the robot hand 21.

The horizontal displacement sensors 28 may measure the horizontal displacement of the inserted robot hand 21, as illustrated in FIGS. 6A, 7A, and 7B. The horizontal displacement sensors 28 may include the first horizontal displacement sensor 24 and the second horizontal displacement sensor 26. The first horizontal displacement sensor 24 may be, for example, an integrated light sensor including a second light-emitting portion 24a that radiates second light L2 and a second light-receiving portion 24b that detects (receives) the second light L2.

The second horizontal displacement sensor 26 may be, for example, an integrated light sensor including a third light-emitting portion 26a that radiates third light L3 and a third light-receiving portion 26b that detects (receives) the third light L3. The second light L2 and the third light L3 may be, for example, laser light. In certain embodiments, the second light-emitting portion 24a and the third light-emitting portion 26b may be LDs that emit laser, and the second light-receiving portion 24b and the third light-receiving portion 26b may be PDs that detect (receive) laser.

When the second light-emitting portion 24a emits the second light L2 onto the wafer W, the second light L2 may be reflected from the wafer W, and the second light-receiving portion 24b may receive the reflected second light L2. When the first horizontal displacement sensor 24 is used, a separation distance (d2 of FIG. 7B) between the top surface of the robot hand 21 and the bottom surface of the wafer W may be measured, as described above with regard to the vertical displacement sensor 22.

When the third light-emitting portion 26a emits the third light L3 onto the wafer W, the third light L3 may be reflected from the wafer W, and the third light-receiving portion 26b may receive the reflected third light L3. When the second horizontal displacement sensor 26 is used, the distance (d2 of FIG. 7B) between the top surface of the robot hand 21 and the bottom surface of the wafer W may be measured, as described above with regard to the vertical displacement sensor 22.

When the separation distance between the first horizontal displacement sensor 24 and the wafer W and the separation distance between the second horizontal displacement sensor 26 and the wafer W are the same, as illustrated in FIG. 7B, a recognition time of the second light L2 by using the second light-receiving portion 24b and a recognition time of the third light L3 by using the third light-receiving portion 26b may be the same. Thus, it may be known that the robot hand 21 is normally carried into the cassette 46, and thus, the horizontal displacement that corresponds to a horizontal movement distance of the robot hand 21 that constitutes the wafer transfer robot 100 may be obtained.

In more detail, when the robot hand 21, on which the first and second horizontal displacement sensors 24 and 26 are mounted, is carried into the cassette 46, as illustrated in FIGS. 5A and 5B, the precise time that the first and second horizontal displacement sensors 24 and 26 are carried into the cassette 46, may be determined depending on whether the second light-receiving portion 24b and the third light-receiving portion 26b receive the second light L2 and the third light L3 simultaneously. Since the horizontal displacement includes components of the X-direction that is the same as a direction (X-direction of FIG. 2) in which the robot hand 21 is carried into the cassette 46, and components of the Y-direction that is perpendicular to the X-direction, at least two horizontal displacement sensors, for example, the first and second horizontal displacement sensors 24 and 26, are used to check the horizontal displacement.

The horizontal displacement of the robot hand 21 that corresponds to the movement distance in the X-direction and the Y-direction of the robot hand 21 may be measured depending on rotation of the robot arm member 11 or the robot axis member 8 that constitutes the robot transfer mechanism 36 of FIGS. 1 and 2 based on the time that the horizontal displacement sensors 28 are simultaneously carried into the cassette 46. Measuring the horizontal displacement will be described later in more detail.

When the separation distance between the first horizontal displacement sensor 24 and the wafer W and the separation distance between the second horizontal displacement sensor 26 and the wafer W are the same, as illustrated in FIG. 7B, a horizontal level of the robot hand 21, i.e., a left/right level of the robot hand 21 according to the Y-axis direction of FIG. 2 and a forward/backward level of the robot hand 21 according to the X-axis direction may be even.

As illustrated in FIG. 7C, the separation distance (d2 of FIG. 7C) between the top surface of the robot hand 21 and the bottom surface of the wafer W, which is measured by using the first horizontal displacement sensor 24, may be different from the separation distance (d3 of FIG. 7C) between the top surface of the robot hand 21 and the bottom surface of the wafer W, which is measured by using the second horizontal displacement sensor 26. In this case, the horizontal level of the robot hand 21, i.e., the left/right level, and the forward/backward level of the robot hand 21 may not be even.

The controller 52 may control the robot transfer mechanism 36 and the robot hand 21 by using the vertical displacement sensor 22 and the horizontal displacement sensors 28, as illustrated in FIGS. 6A and 6B. The controller 52 may calculate a vertical displacement error and a horizontal displacement error of the inserted robot hand 21 with respect to the robot hand 21 that is normally carried into the cassette 46, based on the result of light detection or the measured separation distances of the vertical displacement sensor 22 and the horizontal displacement sensors 28.

The controller 52 may correct the calculated vertical displacement error and horizontal displacement error by reflecting them in position parameters of the robot transfer mechanism (36 of FIG. 1) or by interlocking the robot transfer mechanism 36. When the position parameters of the robot transfer mechanism 36 are corrected, the position of the robot hand 21 may also be changed.

The position parameters of the robot transfer mechanism (36 of FIG. 1) may be position setting parameters of the robot axis member (8 of FIG. 1) and the robot arm member (11 of FIG. 1), for example, rotation angles of the first, second, third, and fourth arms (10, 12, 14, and 16 of FIG. 1) or the movement distance of the robot hand 21.

The position parameters of the robot transfer mechanism 36 may be vertical position coordinates of the robot hand 21, forward/backward position coordinates of the robot hand 21, left/right position coordinates of the robot hand 21, or a rotation angle of the robot hand 21. In particular, the position parameters of the robot transfer mechanism 36, corrected by detecting the vertical displacement, may be the vertical position coordinates of the robot hand 21. The position parameters of the robot transfer mechanism 36, corrected by detecting the horizontal displacement, may be the forward/backward position coordinates of the robot hand 21, the left/right position coordinates of the robot hand 21, or the rotation angle of the robot hand 21.

The controller 52 may be implemented with a computer or a similar device by using software, hardware, or a combination thereof. With hardware, the controller 52 may be provided as application specific integrated circuits (ASICs), digital signal processors (DSPs), digital signal processing devices (DSPDs), programmable logic devices (PLDs), field programmable gate arrays (FPGAs), processors, micro-controllers, microprocessors, or electrical devices for performing a control function that is obvious to one of ordinary skill in the art.

With software, the controller 52 may be implemented with software code written with one or more program languages or a software application, which is stored in a memory and executes in a hardware environment.

As described above, the horizontal displacement sensors 24 and 26 may be used to detect a horizontal displacement along an x-y plane of the robot hand 21 with respect to a wafer, and may also be used to detect whether the robot hand 21 is at an angle with respect to the x-y plane. In either case, the robot hand 21 may be described as being misaligned. Therefore, the horizontal displacement sensors 24 and 26 may be referred to herein as alignment sensors, which are used to detect whether a robot hand 21 is properly aligned (e.g., along a horizontal plane, and in a proper horizontal direction). The vertical displacement sensor 22 may be referred to herein as height sensor.

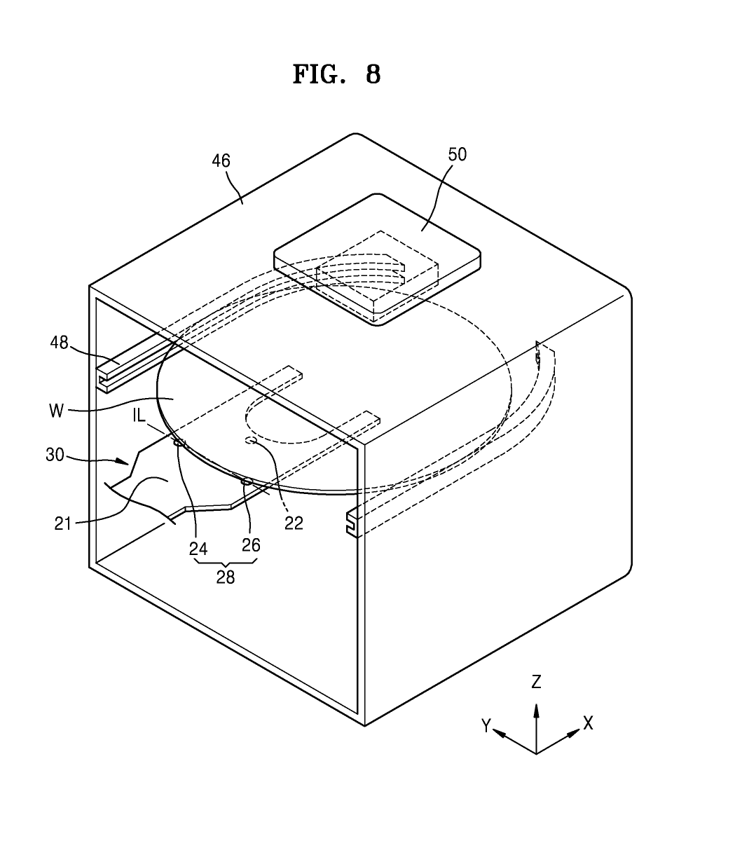

FIGS. 8 through 10 are views of a horizontal displacement of a robot hand with respect to a wafer by using the movement operation of the robot hand according to an exemplary embodiment of the inventive concept.

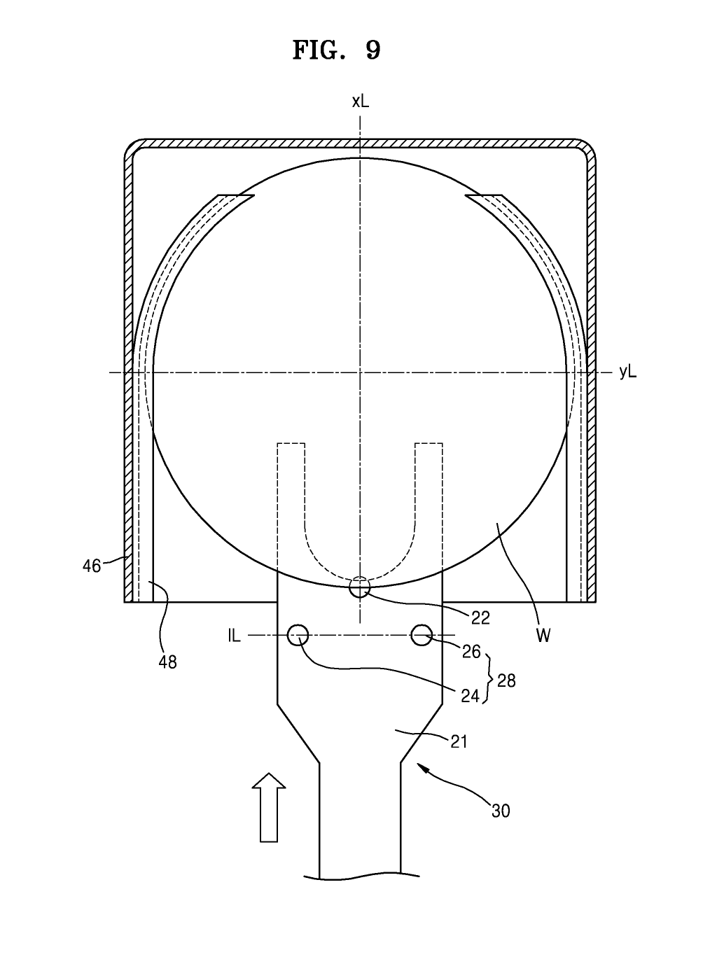

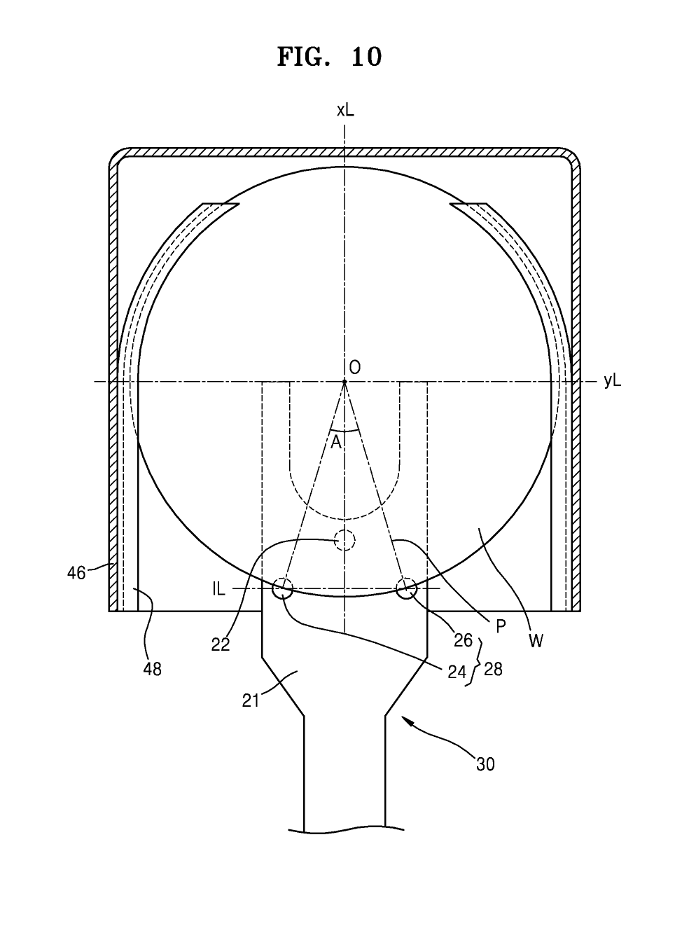

In detail, FIG. 8 is a perspective view for describing an operation in which the robot hand 21 is carried into the cassette 46 that is the wafer-mounting chamber. In FIG. 8, the direction in which the robot hand 21 is carried into the cassette 46 is the X-direction (forward/backward direction), and a direction that is perpendicular to the X-direction is the Y-direction (left/right direction). The vertical movement direction of the robot hand 21 is the Z-direction. FIGS. 9 and 10 are plan views of FIG. 8 from above.

While the robot hand 21 is carried into the cassette 46, the first light-emitting portion (22a of FIG. 6A) of the vertical displacement sensor 22 installed in a front upper portion of the robot hand 21 emits the first light (L1 of FIG. 7A), the first light L1 is reflected from the wafer W, and the first light-receiving portion (22b of FIG. 6A) receives the first light L1. The first light-receiving portion 22b may detect a phase difference of the received first light L1. While the robot hand 21 is carried into the cassette 46, due to a fine step difference of the bottom surface of the wafer W, it may be detected that a phase difference of the first light L1 received by the first light-receiving portion 22b is continuously changed.

Also, while the robot hand 21, on which the horizontal displacement sensors 28 are mounted, is carried into the cassette 46, it may be determined whether the robot hand 21 normally passes through the cassette 46 and a passage time by using the horizontal displacement sensors 28.

In more detail, as illustrated in FIGS. 6A and 7B, the second light-emitting portion (24a of FIG. 6A) of the first horizontal displacement sensor 24 emits the second light (L2 of FIG. 7B), and the second light-receiving portion (24b of FIG. 6A) receives the second light L2 reflected from the wafer W. The third light-emitting portion (26a of FIG. 6A) emits the third light L3, and the third light-receiving portion (26b of FIG. 6A) receives the third light (L3 of FIG. 7B) reflected from the wafer W.

When the second light L2 and the third light L3 are simultaneously received by the second light-receiving portion 24b and the third light-receiving portion 26b, the first and second horizontal displacement sensors 24 and 26 may generate detection signals. The controller 52 may receive the detection signals from the first and second horizontal displacement sensors 24 and 26, thereby determining whether the robot hand 21 passes through the cassette 46 normally and a passage time.

The controller (52 of FIG. 6A) may obtain the time that the robot hand 21 passes through the cassette 46, for example, from the time that the first light-receiving portion 22b receives the first light L1 to the time that carrying of the robot hand 21 is finished, and thus, the horizontal displacement of the robot hand 21 may be calculated. Since the horizontal displacement is a two-dimensional value, a plurality of horizontal displacement sensors, for example, the first and second horizontal displacement sensors 24 and 26, are used to calculate the horizontal displacement.

In certain embodiments, the horizontal displacement may be calculated from a distance at which the robot hand 21 moves from the time that the vertical displacement sensor 22 first passes through the cassette 46 (e.g., first crosses an outer edge of a wafer in the cassette), as illustrated in FIG. 9, to the time that carrying of the robot hand 21 into the cassette 46 is finished, as illustrated in FIG. 10. If the carrying speed of the robot hand 21 is constant, the movement distance of the robot hand 21 may be calculated based on the movement time.

A time that the robot hand 21 moves is a time interval between the time that the first and second horizontal displacement sensors 24 and 26 of the robot hand 21 pass through the cassette 46 (e.g., cross an outer edge of a wafer in the cassette) and the time that carrying of the robot hand 21 into the cassette 46 is finished. The time that the first and second horizontal displacement sensors 24 and 26 of the robot hand 21 pass through the cassette 46 normally is the time that the second light L2 and the third light L3 are simultaneously received by the second light-receiving portion 24b and the third light-receiving portion 26b. The time that carrying of the robot hand 21 into the cassette 46 is finished may be the time that movement of the robot hand 21 is stopped. The time that movement of the robot hand 21 is stopped may be the time that all of the horizontal and vertical displacements of the robot hand 21 are maintained at a constant level.

Also, the time that the horizontal displacement measured by the vertical displacement sensor 22 is maintained at a constant level may be determined as the time that carrying of the robot hand 21 is finished. For example, when carrying of the robot hand 21 is finished, as illustrated in FIG. 10, the wafer transfer robot 100 stops its operation, and the movement of the robot hand 21 is stopped. In this case, the phase difference of the first light L1 detected by the first light-receiving portion 22b of the vertical displacement sensor 22 is maintained at the constant level, and the controller 52 receives signals caused thereby. When the phase difference of the first light L1 detected by the first light-receiving portion 22b is maintained at the constant level, the controller 52 may determine that carrying of the robot hand 21 is finished.

As a result, by using the first and second horizontal displacement sensors 24 and 26, the horizontal displacement of the robot hand 21 may be calculated. The horizontal displacement includes the components of the X-direction that is the same as the carrying direction of the robot hand 21 (X-direction of FIG. 2) and the components of the Y-direction that is perpendicular to the X-direction, as described above, at least two horizontal displacement sensors, for example, the first and second horizontal displacement sensors 24 an 26, may be used to check the horizontal displacement. The horizontal displacement sensors 28 may be disposed at a predetermined angle A at the same distance P from a center O of the robot hand 21 (e.g., center with respect to the Y-direction), carrying of which is finished, as viewed from above. In FIGS. 9 and 10, xL is a central line of the wafer W in a direction in which the robot hand 21 is injected, and yL is a central line of the wafer W that is perpendicular to the direction in which the robot hand 21 is injected. stopped

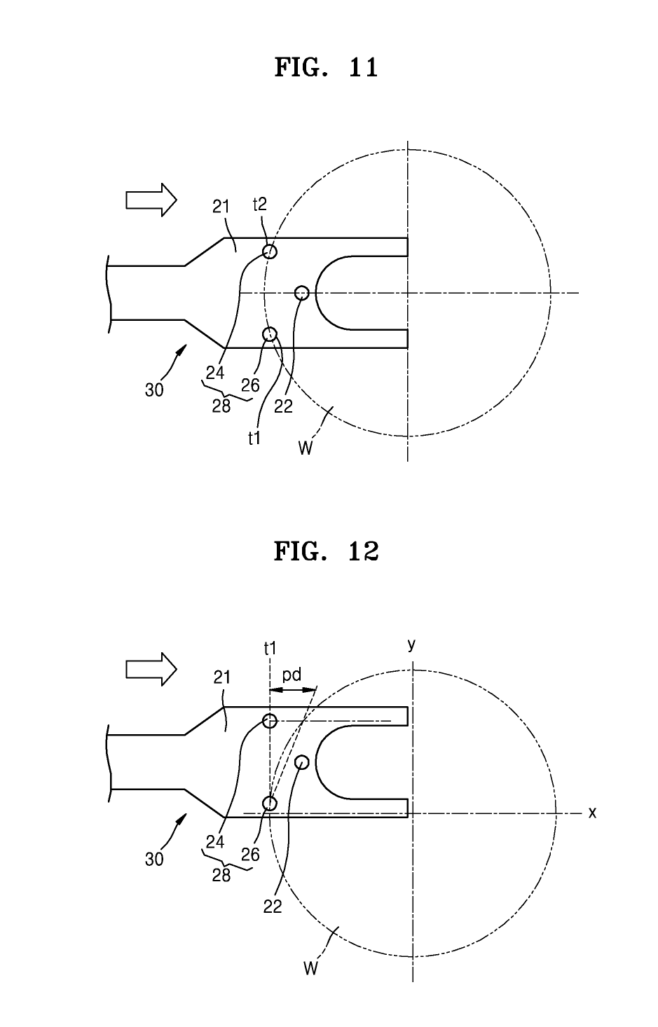

FIGS. 11 through 13 are plan views of an operation of correcting a horizontal displacement of the robot hand with respect to the wafer when the robot hand is carried into a cassette, according to certain exemplary embodiments.

In detail, FIG. 11 illustrates a state in which the robot hand 21 is normally carried to a lower portion of the wafer W in the cassette (46 of FIG. 9). The time that the first and second horizontal displacement sensors 24 and 26 of the robot hand 21 pass into the cassette 46 may be time that the second light L2 and the third light L3 are simultaneously detected by the second light-receiving portion (24b of FIG. 6A) and the third light-receiving portion (26b of FIG. 6A). FIG. 11 illustrates that a first detection time t2 when the second light-receiving portion 24b detects the second light L2 is the same as a second detection time t1 that the third light-receiving portion 26b detects the third light L3 while the robot hand 21 is carried into the cassette 46.

While the robot hand 21 is carried into the cassette 46, the first and second horizontal displacement sensors 24 and 26 may detect the second light L2 and the third light L3 simultaneously and may generate the detection signals. Thus, the controller (52 of FIG. 6A) may receive the detection signals simultaneously and may determine that there is no horizontal displacement error of the robot hand 21 in the left/right direction based on a direction of a carrying path of the robot hand 21.

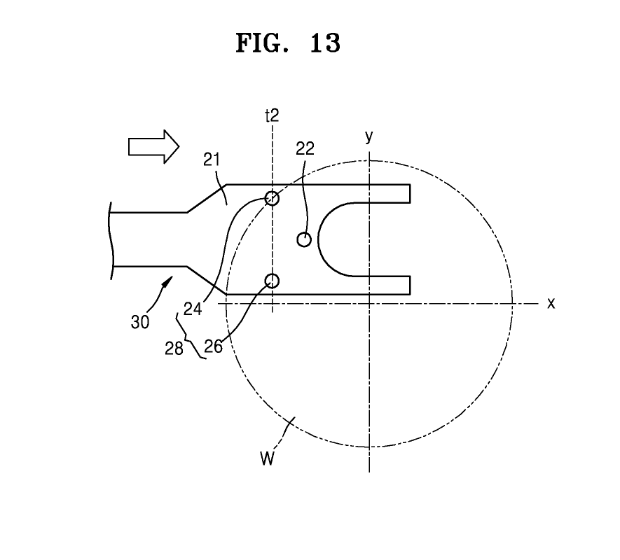

On the other hand, FIGS. 12 and 13 illustrate that the robot hand 21 is abnormally carried into in the cassette (46 of FIG. 9) to the wafer W. FIGS. 12 and 13 illustrate that the first detection time t2 that the second light-receiving portion 24b detects the second light L2 and the second detection time t1 that the third light-receiving portion 26b detects the third light L3 while the robot hand 21 is carried into the cassette 46, are different from each other. The first detection time t2 is the time that the second light L2 and the third light L3 are detected again after the third light L3 is detected.

For example, FIGS. 12 and 13 illustrate a case where the third light-receiving portion 26b on the right side of the carrying path direction of the robot hand 21 first receives the second light L2 while the robot hand 21 is carried into the cassette 46. In this state, the second light-receiving portion 24b on the left side of the carrying path direction of the robot hand 21 does not receive the second light L2. The right-side third light-receiving portion 26b transmits interlock signals (stop signals) to the controller 52, and the left-side second light-receiving portion 24b transmits detection signals to the controller 52.

Thus, the controller 150 may determine that the robot hand 21 is deviated to the left and carried into the cassette 46. In this case, a horizontal displacement error that corresponds to a movement distance difference pd based on a time interval between the second detection time t1 of the third light L3 and the simultaneous first detection time t2 of the second light L2 and the third light L3 after the third light L3 is detected, may be compared with a normal horizontal displacement of the robot hand 21 that is previously input to the controller (52 of FIG. 6A) and thus may be corrected.

By moving along the Y-axis in a downward direction, the position of the robot hand 21 of FIG. 12 may be the same as a position in which the robot hand 21 of FIG. 11 is normally carried into the cassette 46. By moving backward along the X-axis and moving along the Y-axis in the downward direction, the position of the robot hand 21 of FIG. 13 may be the same as a position in which the robot hand 21 of FIG. 11 is normally carried into the cassette 46.

As a result, a two-dimensional deviation of the robot hand 21 when the first detection time t2 is different than the second detection time t1 and the robot hand 21 is deviated, may be corrected based on the horizontal displacement of the robot hand 21 when the robot hand 21 of FIG. 11 is normally carried into the cassette 46. In certain embodiments, a normal horizontal displacement when the robot hand 21 of FIG. 11 is normally carried into the cassette 46 may be previously input to the controller, and the two-dimensional deviation of the robot hand 21 may be corrected based on the normal horizontal displacement of the robot hand 21.

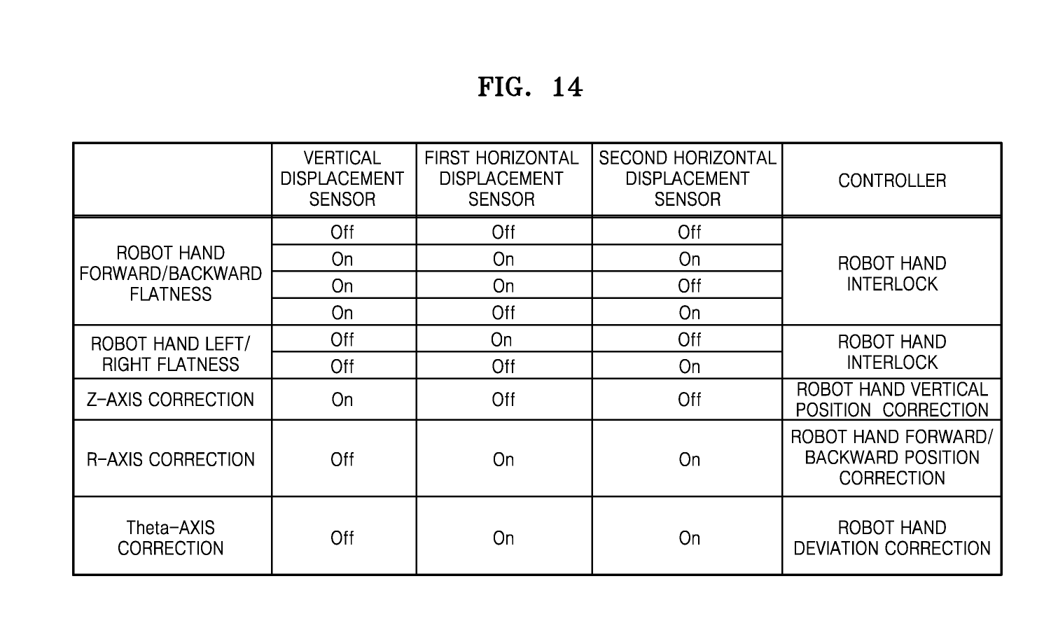

FIG. 14 is a view of a correction content of a robot hand of a controller according to operation signals of displacement sensors, according to certain exemplary embodiments.

In detail, On signals output from the vertical displacement sensor (22 of FIGS. 8 through 10) are signals output when a separation distance between the wafer W and the vertical displacement sensor 22 is not within a normal range (specification range), and Off signals output from the vertical displacement sensor (22 of FIGS. 8 through 10) are signals output when the separation distance between the wafer W and the vertical displacement sensor 22 is within the normal range.

On signals output from the first horizontal displacement sensor (24 of FIGS. 8 through 10) and the second horizontal displacement sensor (26 of FIGS. 8 through 10) are signals output when a separation distance between the wafer W and the first and second horizontal displacement sensors 24 and 26 is within the normal range, and Off signals output from the first horizontal displacement sensor (24 of FIGS. 8 through 10) and the second horizontal displacement sensor (26 of FIGS. 8 through 10) are signals output when the separation distance between the wafer W and the first and second horizontal displacement sensors 24 and 26 is not within the normal range. Each of the normal horizontal ranges may be set to a particular range for which it may be considered that the robot hand 21 is aligned properly (e.g., is within a certain distance from being centered, and/or is horizontally flat), and each of the normal vertical ranges may be set to a particular range for which it may be considered that the robot hand 21 is at a proper distance of a wafer W.

As illustrated in FIG. 14, when signals output from the vertical displacement sensor 22 are Off signals and signals output from one of the first horizontal displacement sensor 24 and the second horizontal displacement sensor 26 are Off signals, forward/backward flatness of the robot hand (21 of FIGS. 8 through 10) is bad. Also, as illustrated in FIG. 14, when signals output from the vertical displacement sensor 22 are On signals and signals output from one of the first horizontal displacement sensor 24 and the second horizontal displacement sensor 26 are On signals, forward/backward flatness of the robot hand (21 of FIGS. 8 through 10) is bad. In this case, the controller (52 of FIG. 6A) may interlock the robot hand (21 of FIGS. 8 through 10). As such, the robot hand may be stopped and operation may temporarily cease. When signals output from the vertical displacement sensor 22 are Off signals and signals output from one of the first horizontal displacement sensor 24 and the second horizontal displacement sensor 26 are On signals, left/right flatness of the robot hand 21 is bad. In this case, the controller 52 may interlock the robot hand 21.

When signals output from the vertical displacement sensor 22 are O signals and signals output from the first horizontal displacement sensor 24 and the second horizontal displacement sensor 26 are Off signals, the vertical position of the robot had 21 is bad. In this case, the controller 52 may correct the vertical position of the robot hand 21.

When signals output from the vertical displacement sensor 22 are Off signals and signals output from the first horizontal displacement sensor 24 and the second horizontal displacement sensor 26 are On signals, the forward/backward position of the robot hand 21 is bad, or the robot hand 21 is deviated. In this case, the controller 52 may correct the forward/backward or deviation of the robot hand 21. In connection with FIG. 14, R axis correction refers to X coordinate correction of the robot hand 21, and theta-axis correction refers to left/right coordinates correction of the robot hand 21. Also, theta-axis correction refers to a rotation angle correction of the robot hand 21. R-Axis correction may be performed by changing the forward/backward coordinates of the robot hand 21. Theta-Axis (A) correction may be performed by changing the left/right coordinates of the robot hand 21, or by changing a rotation angle of the robot hand 21.

Based on the above procedures, in certain embodiments, a plurality of sensor devices on a surface of the robot hand may be used to determine if the robot hand is at a desired height, is aligned to be centered with respect to a wafer in a chamber, and is flat with respect to the wafer. If any of these criteria are not satisfied, then the robot arm can be adjusted and aligned to correct the alignment.

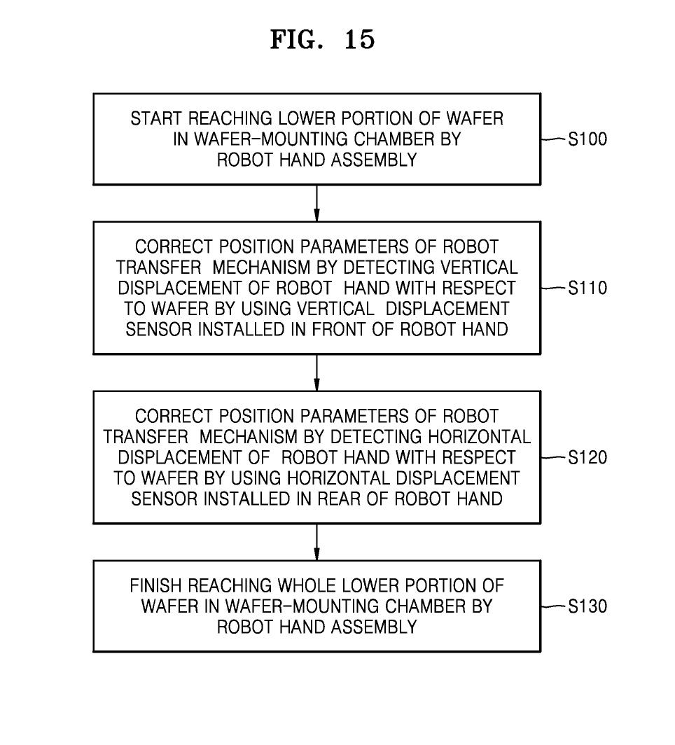

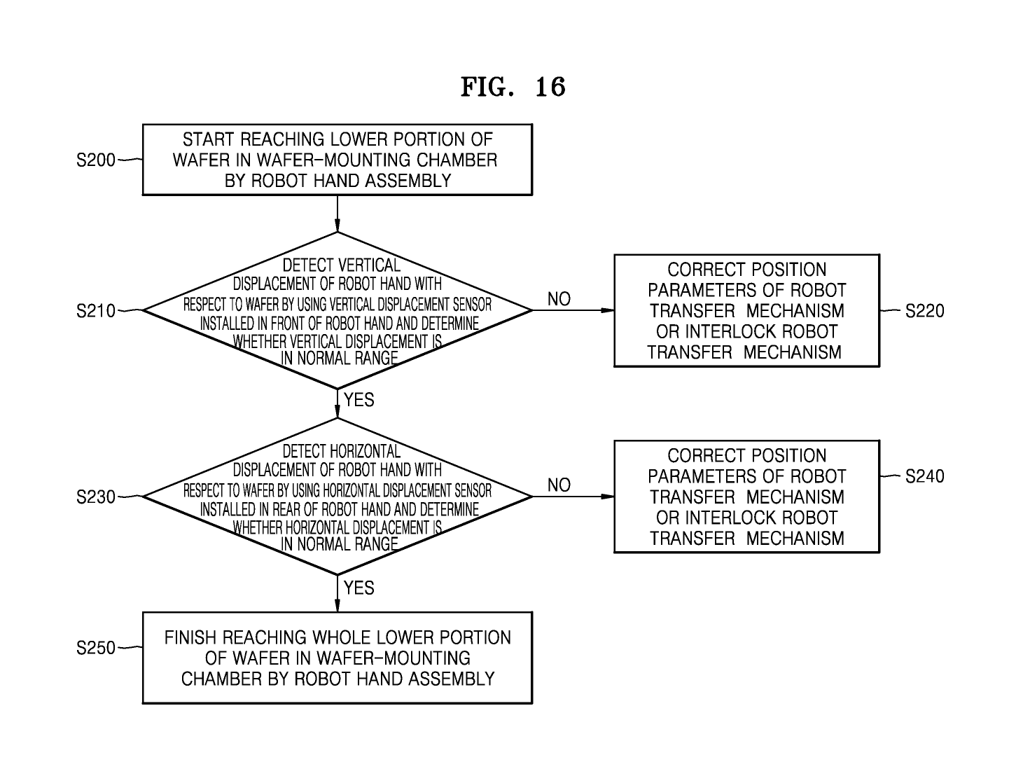

FIG. 15 is a flowchart of a method of controlling a wafer transfer robot by using a robot hand assembly having displacement sensors, according to certain exemplary embodiments.

In detail, as illustrated in FIGS. 8 through 10, the robot hand assembly 30 including the robot hand 21, the vertical displacement sensor 22, and the horizontal displacement sensors 28 reaches the wafer-mounting chamber, for example, a lower, outer portion of the wafer W in the cassette 46 (S100) (e.g., an edge of the wafer W closest to the opening in the wafer-mounting chamber. The vertical displacement sensor 22 may be installed in a front upper portion of the robot hand 21, as previously illustrated. The horizontal displacement sensors 28 may be installed in a rear upper portion of the robot hand 21, as previously illustrated. The robot hand assembly 30 may be carried into the wafer-mounting chamber, i.e., to the lower portion of the wafer W in the cassette 46 by using the wafer transfer robot (100 of FIG. 1).

The vertical displacement of the robot hand 21 is detected using the vertical displacement sensor 22 installed in the front of the robot hand 21, and position parameters of the robot transfer mechanism 36 may be corrected (5110). For example, when a part of the robot hand assembly 30 is carried into the cassette 46 that is the wafer-mounting chamber, the vertical displacement of the robot hand 21 is detected by using the vertical displacement sensor 22 installed in the front of the robot hand 21, and the position parameters of the robot transfer mechanism 36 may be corrected (5110) (e.g., if a vertical adjustment is determined to be warranted).

The first light-emitting portion (22a of FIG. 6A) of the vertical displacement sensor 22 emits first light (L1 of FIG. 7A) onto a bottom surface of the wafer W, and the first light-receiving portion (22b of FIG. 6A) of the vertical displacement sensor 22 receives the first light L1 reflected from the wafer W, as described above. The controller 52 may obtain a distance of flight of the first light L1 based on a time interval between a light-emitting time and a detection (light-receiving) time of the first light L1 or a phase difference, as described above.

Thus, the controller 52 may calculate the vertical displacement of the robot hand 21 by detecting a separation distance between the robot hand 21 and the wafer W based on the distance of flight. When the vertical displacement of the robot hand 21 is calculated, the calculated vertical displacement of the robot hand 21 is compared with a vertical displacement in a normal range that is previously set in the controller 52 so that a vertical displacement error may be calculated. If the vertical displacement is within the normal range (e.g., where the normal range may be a range previously set to be a certain predetermined distance plus or minus a deviation such as 1 or 2 millimeters), then position parameters of the robot transfer mechanism do not need to be corrected. On the other hand, if the displacement is outside the previously set, normal range, position parameters of the robot transfer mechanism (36 of FIG. 1) are corrected based on the vertical displacement error. The position parameters of the robot transfer mechanism, corrected by detected vertical displacement, of the robot hand 21, may be vertical position coordinates of the robot hand 21, as described above.

The position parameters of the robot transfer mechanism 36 may also be corrected by detecting a horizontal displacement of the robot hand 21 with respect to the wafer W by using the first and second horizontal displacement sensors 24 and 26 installed in the rear of the robot hand 21 (S120). For example, when the robot hand assembly 30 is further carried into the cassette 46 that is the wafer-mounting chamber, the first and second horizontal displacement sensors 24 and 26 installed in the rear of the robot hand 21 detect the horizontal displacement of the robot hand 21 and may be used to correct the position parameters of the robot transfer mechanism 36 (S120).

The second light-emitting portion (24a of FIG. 6A) of the first horizontal displacement sensor 24 radiates second light (L2 of FIG. 7B) onto the wafer W, and the second light-receiving portion (24b of FIG. 7B) of the first horizontal displacement sensor 24 receives the second light L2 reflected from the wafer W. The third light-emitting portion (26a of FIG. 6A) of the second horizontal displacement sensor 26 radiates third light (L3 of FIG. 7B) onto the wafer W, and the third light-receiving portion (26b of FIG. 7B) detects the third light L3 reflected from the wafer W.

The horizontal displacement may be calculated based on the time that the first and second horizontal displacement sensors 24 and 26 installed in the robot hand 21 simultaneously pass through the cassette 46, i.e., the time that the second light L2 and the third light L3 are simultaneously detected. When the horizontal displacement is calculated, the horizontal displacement is compared with a horizontal displacement in a normal range that is previously set in the controller 52 so that a horizontal displacement error may be calculated. If the horizontal displacement is within the normal range (e.g., where the normal range may be a range previously set to be a certain predetermined distance plus or minus a deviation such as 5 to 10 millimeters), then position parameters of the robot transfer mechanism do not need to be corrected. On the other hand, if the displacement is outside the previously set, normal range, position parameters of the robot transfer mechanism 36 are corrected based on the horizontal displacement error. The position parameters of the robot transfer mechanism 36, corrected by the detected horizontal displacement, may be forward/backward position coordinates, left/right position coordinates, or a rotation angle of the robot hand 21.

Reaching of the robot hand assembly 30, including the robot hand 21 of the wafer-mounting chamber, i.e., the lower portion of the wafer W in the cassette 46, is then finished (S130). For example, the vertical displacement and the horizontal displacement of the robot hand 21 may be corrected by correcting the position parameters of the robot transfer mechanism 36, and reaching of the robot hand 21 into the cassette 46 that is the wafer-mounting chamber is finished.

Furthermore, while Operations S110, S120, and S130 are performed, a light-receiving amount of the first light-receiving portion 22b of the vertical displacement sensor 22, a light-receiving amount of the second light-receiving portion 24b of the first horizontal displacement sensor 24, and a light-receiving amount of the third light-receiving portion 26b of the second horizontal displacement sensor 26 are compared with each other so that the horizontal flatness of the robot hand 21 may be controlled. Correcting of the position parameters of the robot transfer mechanism 36 by detecting the vertical displacement and the horizontal displacement may be continuously performed from the time that the robot hand 21 starts reaching the lower portion of the wafer of the wafer-mounting chamber to the time that the robot hand 21 finishes reaching the whole lower portion of the wafer of the wafer-mounting chamber.

By continuously and repeatedly performing the above-described operations, a displacement error between the vertical displacement and the horizontal displacement of the robot hand 21 may be continuously obtained. By using this, the tendency of the displacement error when the robot hand 21 is carried into the cassette 46 that is the wafer-mounting chamber may be known, and the displacement error may be remarkably reduced.

FIG. 16 is a flowchart of a method of controlling a wafer transfer robot by using a robot hand assembly having displacement sensors, according to certain exemplary embodiments.

In detail, as illustrated in FIGS. 8 through 10, the robot hand assembly 30, including the robot hand 21, the vertical displacement sensor 22, and the horizontal displacement sensors 28, reaches the wafer-mounting chamber, for example, reaches a lower portion of the wafer W in the cassette 46 (S200). The robot hand assembly 30 may be carried into the wafer-mounting chamber, i.e., into the cassette 46, by using the wafer transfer robot (100 of FIG. 1).

The vertical displacement of the robot hand 21 is detected, and it is determined whether the vertical displacement is in a normal range (S210). For example, when a part of the robot hand assembly 30 is carried into the cassette 46 that is the wafer-mounting chamber, the vertical displacement of the robot hand 21 is detected by using the vertical displacement sensor 22 installed in the front of the robot hand 21, and it is determined whether the vertical displacement is in the normal range.

If the vertical displacement is in the normal range, the next Operation is performed. Otherwise, if the vertical displacement is not in the normal range, the position parameters of the robot transfer mechanism (36 of FIG. 1) are corrected, or the robot transfer mechanism 36 is stopped (interlocked) (S220). For example, if the vertical displacement detected by the vertical displacement sensor 22 is not in the normal range, the position parameters of the robot transfer mechanism 36 are corrected, or the robot transfer mechanism 36 is stopped.

The horizontal displacement of the robot hand 21 is detected, and it is determined whether the horizontal displacement is in a normal range (S230). For example, when the robot hand assembly 30 is further carried into the cassette 46 that is the wafer-mounting chamber, the first and second horizontal displacement sensors 24 and 26 installed in the rear of the robot hand 21 detect the horizontal displacement of the robot hand 21.

If the horizontal displacement is in a normal range, the next Operation is performed. Otherwise, if the horizontal displacement is not in the normal range, the position parameters of the robot transfer mechanism 36 are corrected, or the robot transfer mechanism 30 is stopped (interlocked) (S240). For example, when the horizontal displacement detected by the horizontal displacement sensor is not in the normal range, the position parameters of the robot transfer mechanism 36 are corrected, or the robot transfer mechanism 36 is interlocked.

Reaching of the robot hand assembly 30, including the robot hand 21, and covering the whole lower portion of the wafer W in the cassette 46 that is the wafer-mounting chamber is finished (S250). For example, the vertical displacement and the horizontal displacement of the robot hand 21 may be corrected by correcting the position parameters of the robot transfer mechanism 36, and reaching of the robot hand 21 in the cassette 46 that is the wafer-mounting chamber is then finished.

Hereinafter, an example of a wafer handling system using the above-described wafer transfer robot will be described.

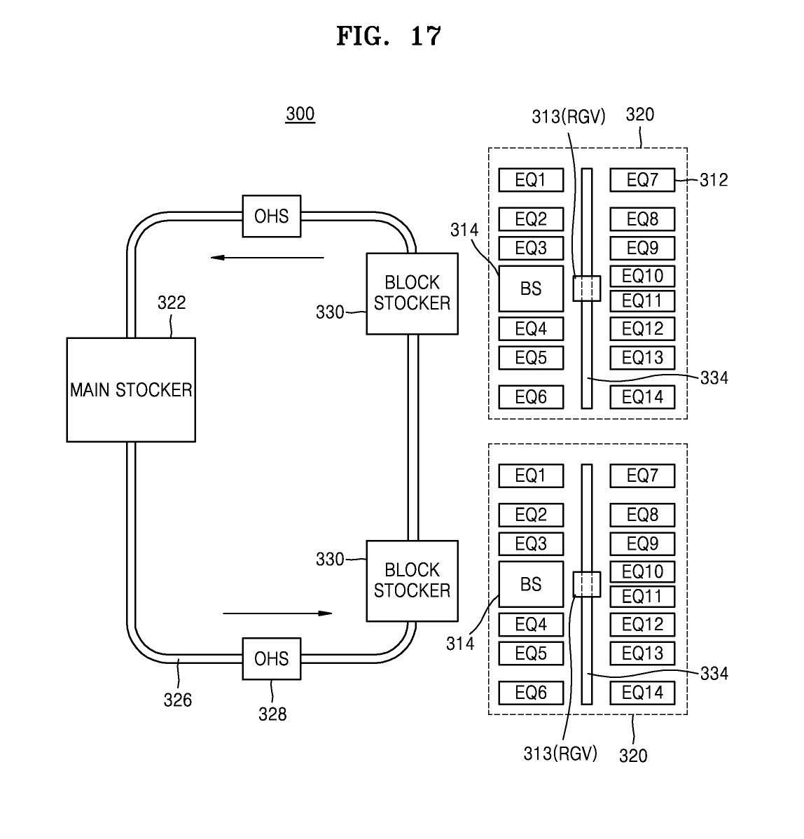

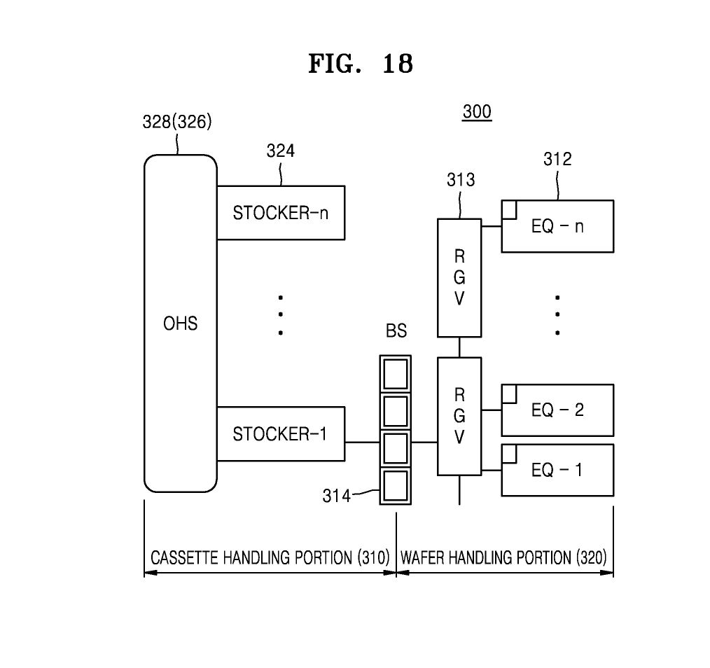

FIG. 17 is a view of the relationship between arrangements of elements of a wafer handling system 300 including a wafer transfer robot, according to an exemplary embodiment of the inventive concept, and FIG. 18 is a schematic view of the wafer handling system 300 illustrated in FIG. 17.

In detail, the wafer handling system 300 according to an exemplary embodiment of the inventive concept may include a cassette handling portion 310 that handles a cassette on which a wafer is stacked, and a wafer handling portion 320 that handles the wafer.

The cassette handling portion 310 may include a main stocker 322 into which the cassette is put, wherein a wafer, on which a part of semiconductor fabrication processes is completely performed, is stacked on the cassette, a cassette transfer device that transfers the cassette put into the main stocker 322 along a cassette travelling rail 326, a block stocker 324 which is transferred by the cassette transfer device 328 and in which the cassette is kept, and a buffer station 314 which is transferred from the block stocker 324 and in which the cassette being on standby for a while so that wafer may be treated, is disposed.

Any type of cassette transfer device 328 that may transfer the cassette on which the wafer is stacked may be used. In the present embodiment, the cassette transfer device 328 may be an overhead shuttle (OHS) that is moved along the cassette traveling rail 250 installed in a ceiling of a clean room.

The wafer handling portion 320 may include a plurality of pieces of process equipment 312 (EQ1-EQ14) that perform semiconductor fabrication processes on the wafer, a wafer transfer robot 313 that transfers the wafer between the buffer station 314 and the plurality of process equipment 312, and a robot transfer rail 334 on which the wafer transfer robot 313 travels. The pieces of process equipment 312 may be handling chambers in which the semiconductor fabrication processes are performed. The wafer transfer robot 100 described in the above embodiment may be used as the wafer transfer robot 313. The process equipment 312 may be, for example, wafer burn-in equipment or wafer test equipment.

The wafer transfer robot 313 may move on the robot transfer rail 334 and thus may be a rail guided vehicle (RGV). FIG. 18 illustrates one or more wafer transfer robots 313 in the wafer handling portion 320. In some cases, only one transfer robot is needed. However, if necessary, a plurality of wafer transfer robots 313 may be installed. The wafer transfer robot 313 may transfer the wafer on which semiconductor fabrication processes are completely performed in one process equipment by using the robot transfer rail 334, to other process equipment by using the buffer station 314.

The buffer station 314 may be optionally installed. When the buffer station 314 is not installed, the wafer may be directly transferred from the block stocker 324 to the process equipment 312 by using the wafer transfer robot 313.

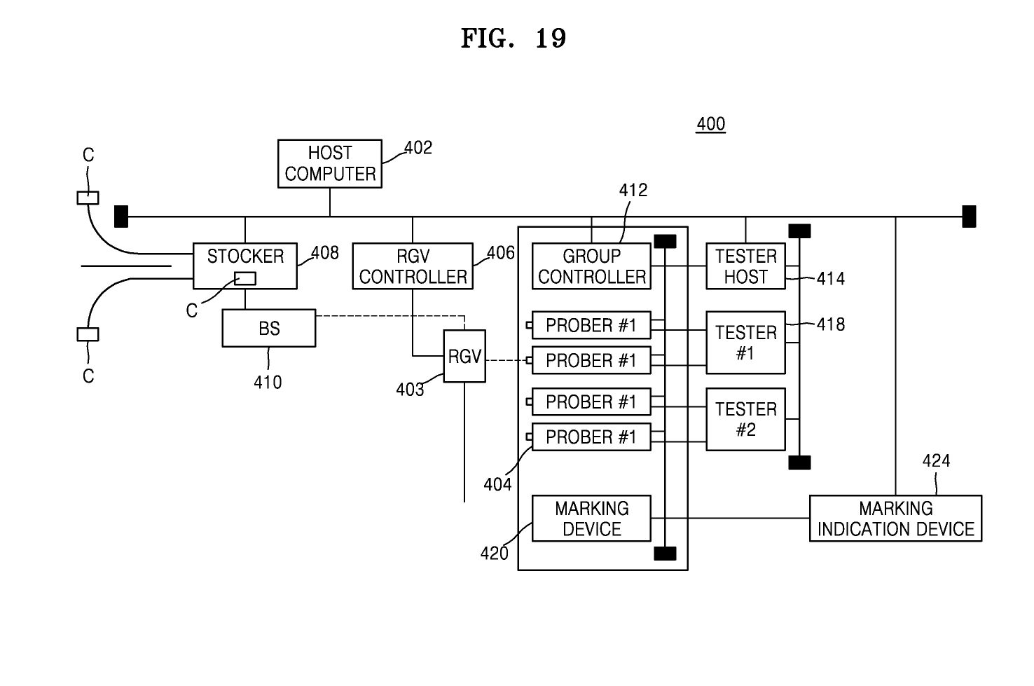

FIG. 19 is a configuration view of an example of a wafer handling system 400 including the wafer transfer robot 313 illustrated in FIG. 17.

In detail, the wafer handling system 400 may include a stocker 408 in which a cassette C, on which a wafer W is mounted, is kept, and a buffer station 410 that temporarily keeps the wafer W therein before an electrical test is performed. The stocker 408 and the buffer station 410 may keep or classify an untested wafer and a tested wafer under control of a host computer 402.

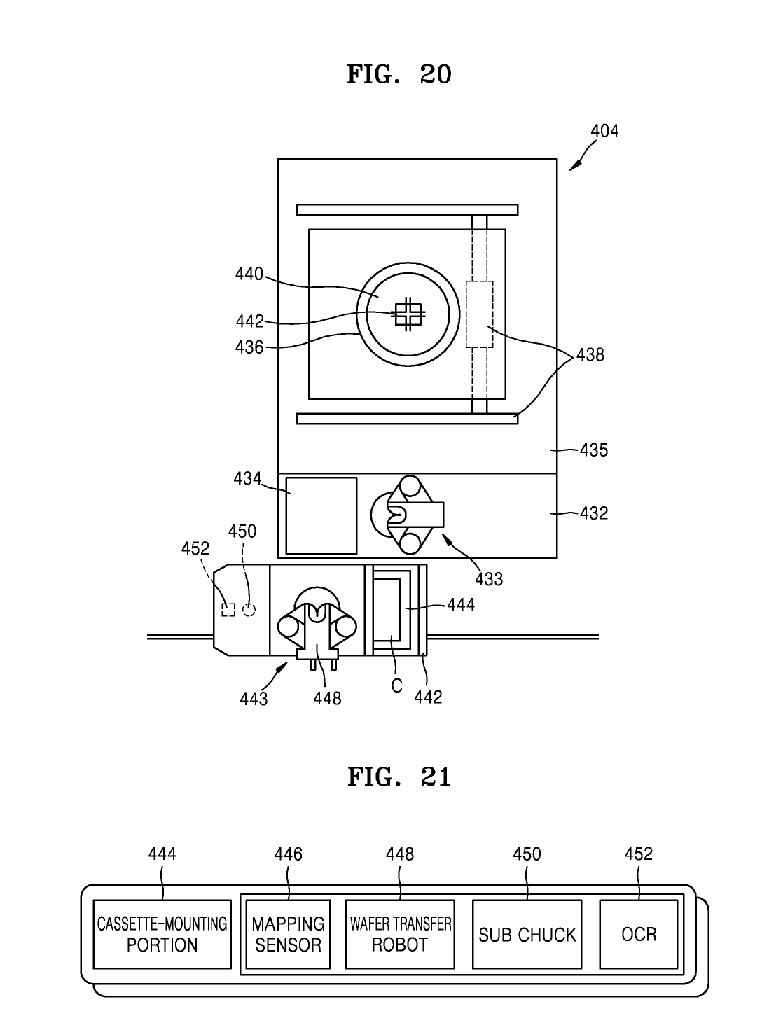

The wafer handling system 400 may include a prober 404 and a tester 418 that are pieces of process equipment for testing electrical characteristics of the wafer W under control of the host computer 402, a wafer transfer robot 403, such as an RGV that transfers the wafer W onto the prober 404, as described above, and an RGV controller 406 that controls the wafer transfer robot 403. The wafer transfer robot 100 described in the above embodiment may be used as the wafer transfer robot 403. In FIG. 20, for convenience, the wafer transfer robot 403 and the RGV controller 406 are separately indicated.

The prober 404 and the tester 418 may be testing devices that perform an electrical test of the wafer W. A plurality of probers 404 may be electrically connected to the host computer 402 through a group controller 412. A plurality of testers 418 may be electrically connected to the host computer 402 through a tester host 414.

In the wafer handling system 400, a marking indication device 424 and a marking device 420 are connected to the host computer 402. The marking indication device 424 is connected to the marking device 420 that performs a predetermined marking based on the result of testing of the wafer W. The marking indication device 424 may instruct the marking device 420 to perform a marking based on data managed by the tester host 414.

FIG. 20 is a schematic view of a prober and the wafer transfer robot 403 of FIG. 19, and FIG. 21 is a block diagram of a schematic configuration of the wafer transfer robot of FIG. 20.

In detail, the prober 404 may include a loader chamber 432 and a prober chamber 435. The loader chamber 432 may include an adaptor unit 434 and a loader chamber wafer transfer robot 433. The adaptor unit 434 may be a buffer station that keeps the wafer therein before the wafer is transferred into the prober chamber 435. The adaptor unit 434 may have a shape of a cassette and may keep the wafer therein. The adaptor unit 434 may be configured to be separated from the loader chamber 432.

The wafer transfer robot 100 described above may be used as the loader chamber wafer transfer robot 433. The loader chamber wafer transfer robot 433 may hold the wafer W by adsorbing the wafer W with vacuum or may release vacuum adsorption, thereby being between the prober chamber 435 and the adaptor unit 434 and transferring the wafer W.

The prober chamber 435 may include a main chuck 436 that vacuum-adsorbs the carried wafer W, an alignment mechanism 438, and a probe card 440. The prober 404 and the wafer W on the main chuck 436 may be in electrical contact with each other. The probe card 440 may be connected to the tester 418 through a test head (not shown).

A wafer transfer robot module 443 may be installed at one side of the prober 404. The wafer transfer robot module 443 may include a cassette-mounting portion 444 which is disposed at one side of a robot body 442 and on which the cassette C is mounted, a mapping sensor 446 that detects an accommodation position of each wafer W accommodated in the cassette C, and a wafer transfer robot 448 that transfers the wafer W between the cassette C and the adaptor unit 434. The wafer transfer robot 100 according to the previous embodiment may be used as the wafer transfer robot 448.

The wafer transfer robot module 443 may include a sub chuck 450 that performs previous alignment of the wafer W, an optical previous alignment sensor (not shown), and an optical character recognition (OCR) 452 that reads an identification (ID) code (not shown) of the wafer W.

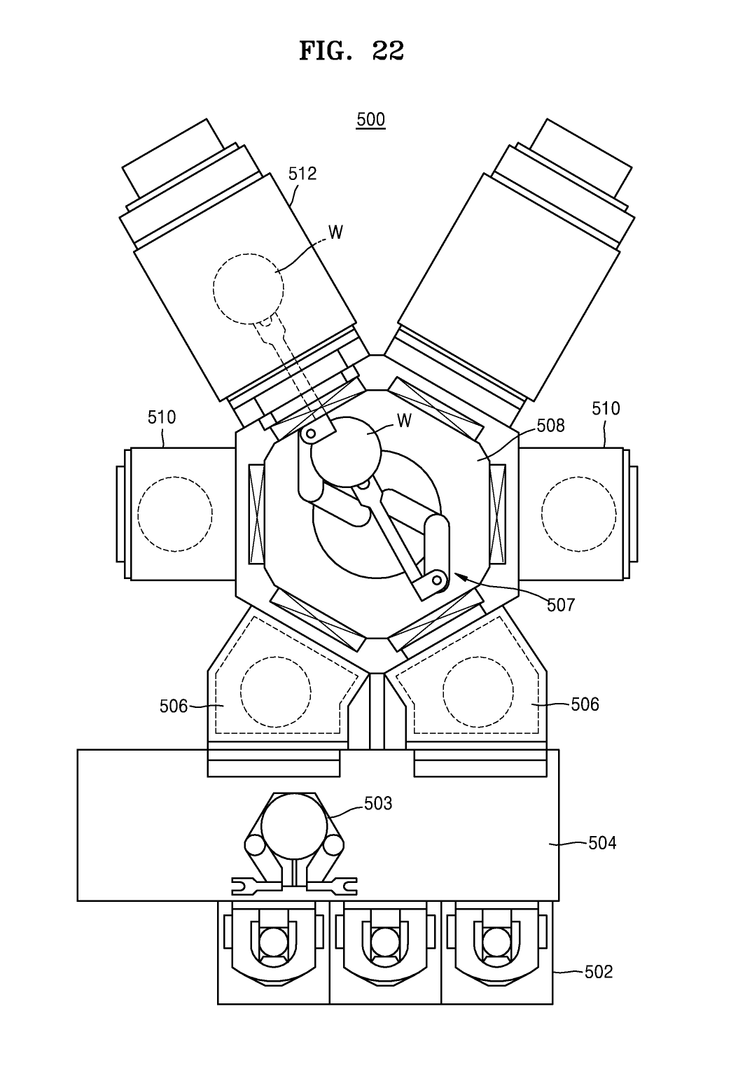

FIG. 22 is a configuration view of a wafer handling system 500 including a wafer transfer robot, according to certain exemplary embodiments.

In detail, the wafer handling system 500 may include a load port 502 that is cluster equipment, a front wafer handling chamber 504 including a first wafer transfer robot 503, a load lock chamber 506, a rear wafer handling chamber 508 including a second wafer transfer robot 507, a cooling chamber 510, and a process handling chamber 512.

The cassette C, on which the wafer W is mounted, may be put into the load port 502. The wafer W mounted on the cassette C in the load port 502 may be put into the load lock chamber 506 by using the first wafer transfer robot 503 disposed in the front wafer handling chamber 504. The wafer transfer robot 100 according to the previous embodiment may be used as the first wafer transfer robot 503.

The load port 502 collects the wafer W from a wafer cassette, and the first wafer transfer robot 503 transports the wafer W into the load lock chamber 506. Also, the first wafer transfer robot 503 may also transport the treated wafer W to the cassette C disposed in the load port 502 again. The load lock chamber 506 may be sealed so as to separate and purge the wafer before the load lock chamber 506 is moved into the rear wafer handling chamber 508, the process handling chamber 512, and the cooling chamber 510.

The wafer W in the load lock chamber 506 may be transferred to the process handling chamber 512 and the cooling chamber 510 by using the second wafer transfer robot 507 in the rear wafer handling chamber 508. Also, the second wafer transfer robot 507 may transfer the wafer W in the process handling chamber 512 and the cooling chamber 510 into the load lock chamber 506 again. The wafer transfer robot 100 according to the previous embodiment may be used as the second wafer transfer robot 507.

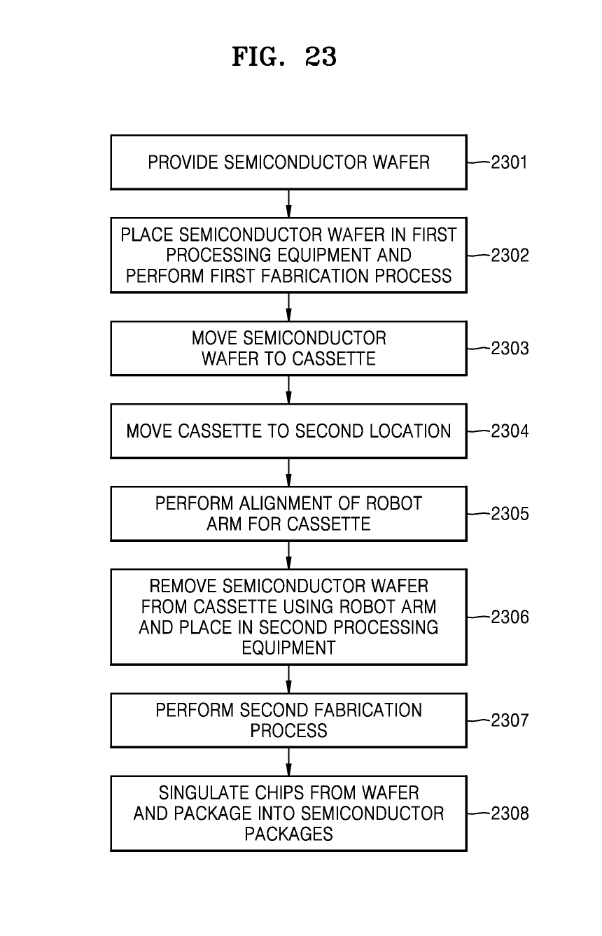

FIG. 23 is a flow chart describing a method of manufacturing a semiconductor device using a wafer transfer robot, according to certain exemplary embodiments. The method may be carried out using one of more of the devices or methods described above. As shown in FIG. 23, in step 2301, a semiconductor wafer is provided. In step 2302, the semiconductor wafer may be placed in a first processing equipment, such as one of the processing equipment devices described above, and at least a first fabrication process may be performed on the semiconductor wafer. In step 2303, the semiconductor wafer may be moved to a cassette, such as one of the cassettes described above, using a robot, including a robot transfer mechanism such as described above. The cassette may then be transferred to a different location where a second processing equipment is located (step 2304). Next, the semiconductor wafer may be removed from the cassette, for example, using robot, including a robot transfer mechanism such as described above. In removing the semiconductor wafer from the cassette, a method such as described above, of determining if a robot arm of a robot is properly aligned, and if not, correcting the alignment of the robot arm prior to removing the semiconductor wafer from the cassette, may be performed (step 2305). Then, the semiconductor wafer may be removed from the cassette by the robot arm and placed into the second processing equipment (step 2306). A second fabrication process may then be performed on the semiconductor wafer (step 2307). Additional steps such as steps 2303 through 2307 may be additionally performed to fabricate a plurality of semiconductor devices, such as semiconductor chips on the wafer. Then, in step 2308, the semiconductor chips may be singulated from the wafer, and may be packaged into semiconductor packages, for example, each including a package substrate on which at least a first semiconductor chip is mounted, and a molding material covering and protecting the semiconductor chip. In certain embodiments, the packaging steps may be performed prior singulation. In other embodiments, the packaging steps may be performed after singulation

While the inventive concept has been particularly shown and described with reference to exemplary embodiments thereof, it will be understood that various changes in form and details may be made therein without departing from the spirit and scope of the following claims.

1. A wafer transfer robot comprising:
a robot transfer mechanism comprising a robot axis member and a robot arm member connected to the robot axis member;
a robot hand connected to the robot arm member of the robot transfer mechanism and for transferring a wafer by using the robot transfer mechanism;
a vertical displacement sensor installed in an upper side of the robot hand; and
a plurality of horizontal displacement sensors installed in the upper side of the robot hand and separate from each other along a virtual line that is perpendicular to a bilaterally symmetric axis of the robot hand.

2. The wafer transfer robot of claim 1, wherein the vertical displacement sensor and the plurality of horizontal displacement sensors are installed to be flush with a top surface of the robot hand.

3. The wafer transfer robot of claim 1, wherein the vertical displacement sensor
is an integrated light sensor comprising a first light-emitting portion that radiates first light and a first light-receiving portion that detects the first light.

4. The wafer transfer robot of claim 1, wherein the horizontal displacement sensors are installed to be separate from the vertical displacement sensor.

5. The wafer transfer robot of claim 1, wherein the horizontal displacement sensors comprise a first horizontal displacement sensor and a second horizontal displacement sensor, and wherein the first horizontal displacement sensor is an integrated light sensor comprising a second light-emitting portion that radiates second light and a second light-receiving portion that detects the second light, and
the second horizontal displacement sensor is an integrated light sensor comprising a third light-emitting portion that radiates third light and a third light-receiving portion that detects the third light.

6. The wafer transfer robot of claim 1, further comprising a controller, wherein the controller controls the robot transfer mechanism and the robot hand by using the vertical displacement sensor and the horizontal displacement sensors.

7. The wafer transfer robot of claim 1, wherein:
the robot transfer mechanism is configured to move the robot hand to a wafer-mounting chamber into which a wafer is carried by using the robot transfer mechanism; and
the plurality of horizontal displacement sensors are configured to detect a horizontal displacement of the robot hand.

8. The wafer transfer robot of claim 7, further configured to, when the robot hand is carried into the wafer-mounting chamber, radiate first light from a first light-emitting portion of the vertical displacement sensor onto the wafer and detect the first light reflected from the wafer by a first light-receiving portion of the vertical displacement sensor.

9. The wafer transfer robot of claim 8, wherein the vertical displacement sensor is a light sensor that detects a vertical displacement of the robot hand by using a movement distance of the first light.

10. The wafer transfer robot of claim 7, wherein the horizontal displacement sensors comprise a first horizontal displacement sensor and a second horizontal displacement sensor, and wherein the first horizontal displacement sensor and the second horizontal displacement sensor are disposed at the same distance from a center of the wafer when the robot hand moves to a position in which the robot hand is normally carried into the wafer-mounting chamber.

11. The wafer transfer robot of claim 7, wherein the wafer-mounting chamber is a cassette on which the wafer is capable of being mounted, or a handling chamber on which in which semiconductor fabrication processes are performed.

12. A wafer transfer robot comprising:
a robot transfer mechanism comprising a robot axis member and a robot arm member connected to the robot axis member;
a robot hand connected to the robot arm member of the robot transfer mechanism and configured to be moved to a wafer-mounting chamber into which a wafer is carried by using the robot transfer mechanism;
a vertical displacement sensor installed in an upper side of the robot hand and configured to detect a vertical displacement of the robot hand when the robot hand moves into the wafer-mounting chamber;
a plurality of horizontal displacement sensors installed in the upper side of the robot
hand and separate from each other along a virtual line that is perpendicular to a movement direction of the robot hand when moving into the wafer-mounting chamber, and configured to detect a horizontal displacement of the robot hand when the robot hand moves into the wafer-mounting chamber; and
a controller configured to calculate a vertical displacement error and a horizontal displacement error of the robot hand that is normally carried into the wafer-mounting chamber when the robot hand moves into the wafer-mounting chamber, and configured to correct position parameters of the robot transfer mechanism based on the calculated vertical displacement error and horizontal displacement error and to interlock the robot transfer mechanism.

13. The wafer transfer robot of claim 12, wherein the vertical displacement sensor is a light sensor comprising a first light-emitting portion that radiates first light onto the wafer and a first light-receiving portion that detects the first light reflected from the wafer, wherein the controller is configured to detect a vertical displacement of the robot hand by using a movement distance of the first light.

14. The wafer transfer robot of claim 12, wherein the plurality of horizontal displacement sensors comprise a first horizontal displacement sensor and a second horizontal displacement sensor, and
the first horizontal displacement sensor comprises a second light-emitting portion that radiates second light onto the wafer and a second light-receiving portion that detects the second light reflected from the wafer, and the second horizontal displacement sensor comprises a third light-emitting portion that radiates third light onto the wafer and a third light-receiving portion that detects the third light reflected from the wafer, and
the horizontal displacement sensors are light sensors that detect a horizontal displacement of the robot hand by using the second light and the third light that are simultaneously detected.

15. The wafer transfer robot of claim 12, wherein position parameters of the robot transfer mechanism are vertical position coordinates, forward/backward position coordinates, left/right position coordinates, or a rotation angle of the robot hand.

16. A method comprising:
starting moving a robot hand assembly comprising a robot hand connected to a robot transfer mechanism toward an outer edge of a wafer in a wafer-mounting chamber, wherein the robot hand includes a vertical displacement sensor installed in a front upper portion of the robot hand and horizontal displacement sensors installed in a rear upper portion of the robot hand and separate from each other along a virtual line that is perpendicular to the movement direction of the robot hand;
correcting position parameters of the robot transfer mechanism by detecting a vertical displacement of the robot hand with respect to the wafer by using the vertical displacement sensor as a part of the robot hand is moved into the wafer-mounting chamber;
correcting the position parameters of the robot transfer mechanism by detecting a horizontal displacement of the robot hand with respect to the wafer by using the horizontal displacement sensors as the robot hand is further moved into the wafer-mounting chamber; and
finishing the moving of the robot hand with respect to the wafer in the wafer-mounting chamber.

17. The method of claim 16, wherein the vertical displacement sensor comprises a first light-emitting portion that radiates first light onto the wafer and a first light-receiving portion that detects the first light reflected from the wafer, and the vertical displacement is detected based on a time interval between a time that the first light is radiated and a time that the first light is detected, or a phase difference.

18. The method of claim 16, wherein the horizontal displacement sensors comprise a first horizontal displacement sensor and a second horizontal displacement sensor that is separate from the first horizontal displacement sensor, and
the first horizontal displacement sensor comprises a second light-emitting portion that radiates second light onto the wafer and a second light-receiving portion that detects the second light reflected from the wafer, and the second horizontal displacement sensor comprises a third light-emitting portion that radiates third light onto the wafer and a third light-receiving portion that detects the third light reflected from the wafer, and
the horizontal displacement is detected based on a time when the horizontal displacement sensors detect the second light and the third light simultaneously.

19-20. (canceled)

21. The method of claim 17, wherein position parameters of the robot transfer mechanism, corrected by detecting the vertical displacement, are vertical position coordinates of the robot hand.

22. The method of claim 17, wherein position parameters of the robot transfer mechanism, corrected by detecting the horizontal displacement, are forward/backward position coordinates, left/right position coordinates, and a rotation angle of the robot hand.

23-31. (canceled)
